(19) United States
(12) Patent Application Publication
(10) Pub. No.: US 2025/0046583 A1
(43) Pub. Date: Feb. 6, 2025

(54) SUBSTRATE PROCESSING SYSTEM

(71) Applicant: Tokyo Electron Limited, Tokyo (JP)

(72) Inventors: Tatsuru OKAMURA, Miyagi (JP); Masatomo KITA, Miyagi (JP); Young tae SONG, Miyagi (JP)

(73) Assignee: Tokyo Electron Limited, Tokyo (JP)

(21) Appl. No.: 18/926,627

(22) Filed: Oct. 25, 2024

Related U.S. Application Data
(63) Continuation of application No. PCT/JP2023/034968, filed on Sep. 26, 2023.

(30) Foreign Application Priority Data
Sep. 30, 2022 (JP) 2022-157769

(51) Int. Cl. H01J 37/32

(52) U.S. Cl. CPC H01J 37/32807; H01J 37/32642; H01J 37/32715; H01J 37/32899

(57) ABSTRACT

A substrate processing system disclosed here includes a vacuum transfer chamber, a plurality of substrate processing modules, a ring stocker, a transfer robot, and control circuitry. The plurality of substrate processing modules and the ring stocker are connected to the vacuum transfer chamber. When the transfer robot is transferring only a new edge ring using one of at least two end effectors, the controller controls the transfer robot to transfer a substrate via the vacuum transfer chamber using an unused end effector of the at least two end effectors in response to a substrate transfer request.

### CROSS-REFERENCE TO RELATED APPLICATIONS

This application is a bypass continuation application of international application No. PCT/JP2023/034968 having an international filing date of Sep. 26, 2023 and designating the United States, the international application being based upon and claiming the benefit of priority from Japanese Patent Application No. 2022-157769, filed on Sep. 30, 2022, the entire contents of each are incorporated herein by reference in their entirety.

### TECHNICAL FIELD

Exemplary embodiments of the present disclosure relate to a substrate processing system and a transfer method.

### BACKGROUND

A plasma processing apparatus is used for processing a substrate. The plasma processing apparatus includes a chamber and a substrate support. The substrate support is provided in the chamber and supports a focus ring (or an edge ring) disposed on the substrate support. Patent Literature 1 discloses a technique for replacing an edge ring of a plasma processing apparatus without exposing a space in the chamber to the atmosphere.

### CITATION LIST

### Patent Documents

Patent Document 1: JP2018-10992A

### SUMMARY

The present disclosure provides a technique for increasing productivity of a substrate processing system.

In one exemplary embodiment, a substrate processing system is provided. The substrate processing system includes a vacuum transfer chamber, a plurality of substrate processing modules, a ring stocker, a transfer robot, and a controller (e.g., control circuitry). The plurality of substrate processing modules are connected to the vacuum transfer chamber. Each of the plurality of substrate processing modules includes a substrate processing chamber and a substrate support. The substrate support is disposed in the substrate processing chamber and supports a substrate on the substrate support and an edge ring that surrounds the substrate. The ring stocker is connected to the vacuum transfer chamber and configured to store at least one edge ring. The transfer robot is disposed in the vacuum transfer chamber, and has at least two end effectors. The controller is configured to (a) determine whether the transfer robot is transferring an edge ring via the vacuum transfer chamber in response to a substrate transfer request, (b) determine whether the edge ring that is being transferred is transferred from the ring stocker to any one of the plurality of substrate processing modules, or the edge ring that is being transferred is transferred from any one of the plurality of substrate processing modules to the ring stocker when it is determined in (a) that the transfer robot is transferring the edge ring, and (c) control the transfer robot to suspend the transfer of the edge ring that is being transferred from the ring stocker to any one of the plurality of substrate processing modules, and transfer the substrate via the vacuum transfer chamber using an unused end effector of the at least two end effectors when it is determined in (b) that the edge ring that is being transferred is transferred from the ring stocker to any one of the plurality of substrate processing modules.

According to one exemplary embodiment, it is possible to increase productivity of the substrate processing system.

### BRIEF DESCRIPTION OF DRAWINGS

FIG. 1 shows a substrate processing system according to an exemplary embodiment.

FIG. 2 is a diagram showing a stocker module according to an exemplary embodiment.

FIG. 3 is a diagram schematically showing a plasma processing apparatus according to an exemplary embodiment.

FIG. 4 is a partially enlarged cross-sectional view showing a substrate support of the plasma processing apparatus according to an exemplary embodiment.

FIG. 5 is a flowchart showing a transfer method according to an exemplary embodiment.

FIG. 6 is a flowchart showing substrate transfer according to an exemplary embodiment.

FIG. 7 is a flowchart showing a transfer method according to another exemplary embodiment.

FIG. 8 is a flowchart showing a transfer method according to still another exemplary embodiment.

FIG. 9 is a schematic diagram of a plasma processing apparatus according to another exemplary embodiment.

FIG. 10 is a diagram schematically showing a substrate support according to another exemplary embodiment.

FIG. 11 is a partially enlarged view showing the substrate support according to another exemplary embodiment.

FIG. 12 is a partially enlarged cross-sectional view of the edge ring according to an exemplary embodiment.

FIG. 13 is a flowchart showing a transfer method according to still another exemplary embodiment.

FIG. 14 is a flowchart showing a transfer method according to still another exemplary embodiment.

FIG. 15 is a diagram showing a transfer module according to an exemplary embodiment.

FIG. 16 is a plan view showing an example pick.

FIG. 17 is a side view showing an example pick.

### DETAILED DESCRIPTION

Hereinafter, various exemplary embodiments will be described in detail with reference to the drawings. Further, like reference numerals will be given to like or corresponding parts throughout the drawings.

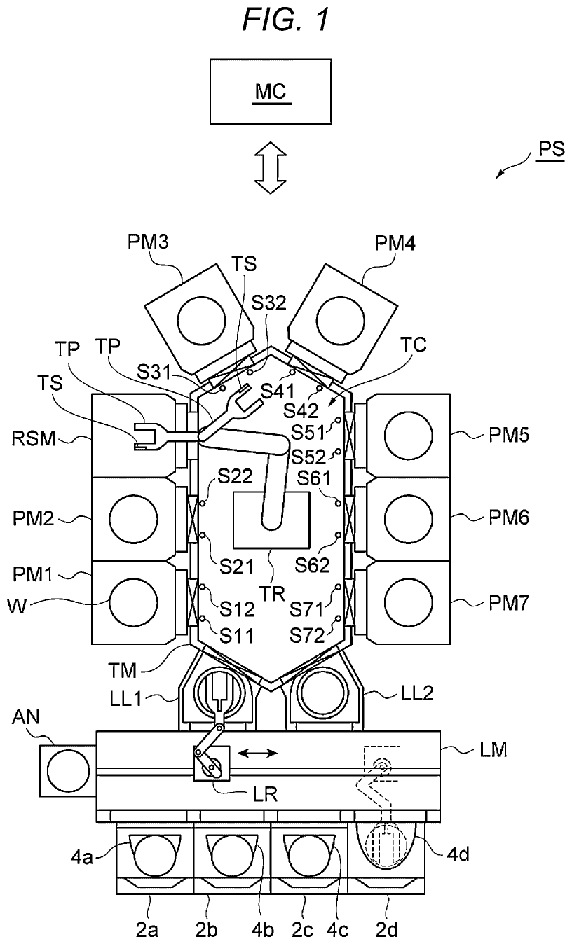

FIG. 1 shows a substrate processing system according to an exemplary embodiment. A substrate processing system PS shown in FIG. 1 includes a transfer module TM, a plurality of processing modules PM1 to PM7 (a plurality of substrate processing modules), and a controller MC. The substrate processing system PS may further include stages 2a to 2d, containers 4a to 4d, a loader module LM, an aligner AN, a load-lock module LL1, a load-lock module LL2, and a stocker module RSM (a ring stocker). The number of the stages, the number of the containers, and the number of the load-lock modules in the substrate processing system PS may be any number of one or more. The number of the processing modules in the substrate processing system PS may be any number of two or more.

The stages 2a to 2d are arranged along an edge of the loader module LM. The containers 4a to 4d are placed on the stages 2a to 2d, respectively. Each of the containers 4a to 4d is, for example, a container referred to as a front opening unified pod (FOUP). Each of the containers 4a to 4d is configured to accommodate a substrate W therein.

The loader module LM includes a transfer chamber. Pressure in the transfer chamber of the loader module LM is set to atmospheric pressure. The loader module LM includes a transfer robot LR. The transfer robot LR is controlled by the controller MC. The transfer robot LR is configured to transfer the substrate W via the transfer chamber of the loader module LM. The transfer robot LR can transfer the substrate W between each of the containers 4a to 4d and the aligner AN, between the aligner AN and each of the load-lock modules LL1 and LL2, and between each of the load-lock modules LL1 and LL2 and each of the containers 4a to 4d. The aligner AN is connected to the loader module LM. The aligner AN is configured to adjust a position (alignment) of the substrate W.

The load-lock module LL1 and the load-lock module LL2 are connected between the transfer chamber of the loader module LM and a transfer chamber TC of the transfer module TM. Each of the load-lock module LL1 and the load-lock module LL2 has a preliminary decompression chamber. A gate valve is provided between the preliminary decompression chamber of each of the load-lock module LL1 and the load-lock module LL2 and the transfer chamber of the loader module LM. Further, a gate valve is provided between the preliminary decompression chamber of each of the load-lock module LL1 and the load-lock module LL2 and the transfer chamber TC of the transfer module TM.

The transfer module TM includes the transfer chamber TC (a vacuum transfer chamber) and a transfer robot TR. The transfer chamber TC is configured such that an interior space of the transfer chamber TC is decompressible (e.g., can have a lowered pressure, including below atmospheric pressure). The transfer robot TR includes a pick TP (an end effector). The transfer robot TR may include at least two picks TP. In an example shown in the drawing, the transfer robot TR includes two picks TP. One of the two picks TP is provided above the other one. The transfer robot TR is configured to transfer the substrate W disposed on any one of the two picks TP via the transfer chamber TC. The transfer robot TR is controlled by the controller MC.

The transfer module TM may be provided with position detection sensors S11 and S12. The position detection sensors S11 and S12 are provided on a transfer path of the substrate W and an edge ring from the transfer module TM to the processing module PM1. The position detection sensors S11 and S12 are used to correct positions of the substrate W and the edge ring transferred from the transfer module TM to the processing module PM1. The position detection sensors S11 and S12 are provided, for example, in the vicinity of a gate valve that partitions the transfer module TM and the processing module PM1. The position detection sensors S11 and S12 are disposed such that, for example, a distance between the position detection sensors S11 and S12 is smaller than an outer diameter of the substrate W and smaller than an inner diameter of the edge ring. Similar to the position detection sensors S11 and S12, the transfer module TM may be provided with position detection sensors S21, S22, S31, S32, S41, S42, S51, S52, S61, S62, S71, and S72. The position detection sensors S21 and S22 are provided on a transfer path of the substrate W and the edge ring from the transfer module TM to the processing module PM2. The position detection sensors S31 and S32 are provided on a transfer path of the substrate W and the edge ring from the transfer module TM to the processing module PM3. The position detection sensors S41 and S42 are provided on a transfer path of the substrate W and the edge ring from the transfer module TM to the processing module PM4. The position detection sensors S51 and S52 are provided on a transfer path of the substrate W and the edge ring from the transfer module TM to the processing module PM5. The position detection sensors S61 and S62 are provided on a transfer path of the substrate W and the edge ring from the transfer module TM to the processing module PM6. The position detection sensors S71 and S72 are provided on a transfer path of the substrate W and the edge ring from the transfer module TM to the processing module PM7.

In an exemplary embodiment, the transfer robot TR is configured to transfer a ring member for the substrate support in any one of the plurality of processing modules PM1 to PM7. The ring member is an edge ring, a cover ring, or a second ring of an edge ring which will be described later. The ring member is transferred by being disposed on any one of the two picks TP. When the ring member is used in a processing module, the ring member may be transferred using a lower pick of the two picks TP. When the ring member is a replacement (or a new ring member) to be replaced with a used ring member, the ring member may be transferred using an upper pick of the two picks TP. The new ring member may be an unused ring member, a recycled ring member, or a ring member that is less consumed than a used ring member.

Each pick TP includes a sensor TS. The sensor TS is an optical sensor and is configured to measure a position of the ring member on the substrate support.

Each of the processing modules PM1 to PM7 is an apparatus configured to execute dedicated substrate processing, and includes a processing chamber (a substrate processing chamber). A gate valve is provided between the processing chamber and the transfer chamber TC. At least one of the processing modules PM1 to PM7 is a plasma processing apparatus. Details of the plasma processing apparatus will be described later.

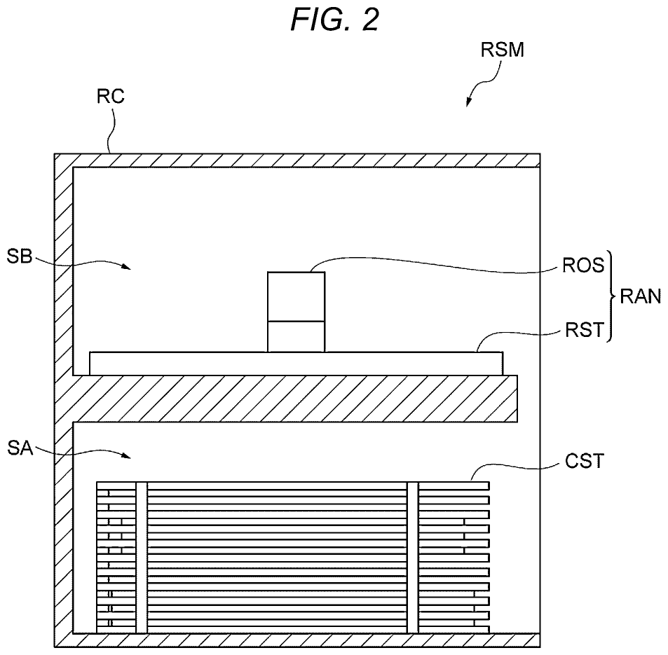

The stocker module RSM (a ring stocker) is connected to the transfer chamber TC via a gate valve. FIG. 2 is a diagram showing a stocker module according to an exemplary embodiment. The stocker module RSM includes a chamber RC. An interior space of the chamber RC can be decompressed. The chamber RC has a first space SA and a second space SB. The first space SA may be provided below the second space SB. A cassette CST is accommodated in the first space SA. The cassette CST is configured to store a ring member therein.

An aligner RAN is accommodated in the second space SB. The aligner RAN is configured to adjust a position (alignment) of a ring member disposed on a stage RST. The aligner RAN may include the stage RST and an optical sensor ROS. The stage RST is configured to be rotatable around a central axis of the stage RST. The optical sensor ROS is configured to optically detect a position of the ring member on the stage RST. The aligner RAN may be configured to adjust the position of the ring member according to the position detected by the optical sensor ROS. In an exemplary embodiment, the aligner RAN is configured to detect an edge ring ER and a cover ring CR, and align the edge ring ER and the cover ring CR with each other. In one example, the aligner RAN includes a line sensor and a light-emitting unit that faces the line sensor (the line sensor and the light-emitting unit are respectively disposed above and below the ring member). The line sensor detects an amount of light emitted from the light-emitting unit, and detects a position of the ring member by using a fact that the detected light amount changes depending on the presence or absence of an orientation flat or notch on the ring member. The aligner RAN may be configured such that the aligner RAN can align the edge ring ER at an inner portion of the line sensor and align the cover ring CR at an outer portion of the line sensor.

The controller MC is configured to control individual components of the substrate processing system PS. The controller MC may be a computer including a processor, a storage device, an input device, a display device, and the like. The controller MC executes a control program stored in the storage device and controls the individual components of the substrate processing system PS based on recipe data stored in the storage device. A transfer method according to various exemplary embodiments to be described later can be executed in the substrate processing system PS by controlling the individual components of the substrate processing system PS by the controller MC.

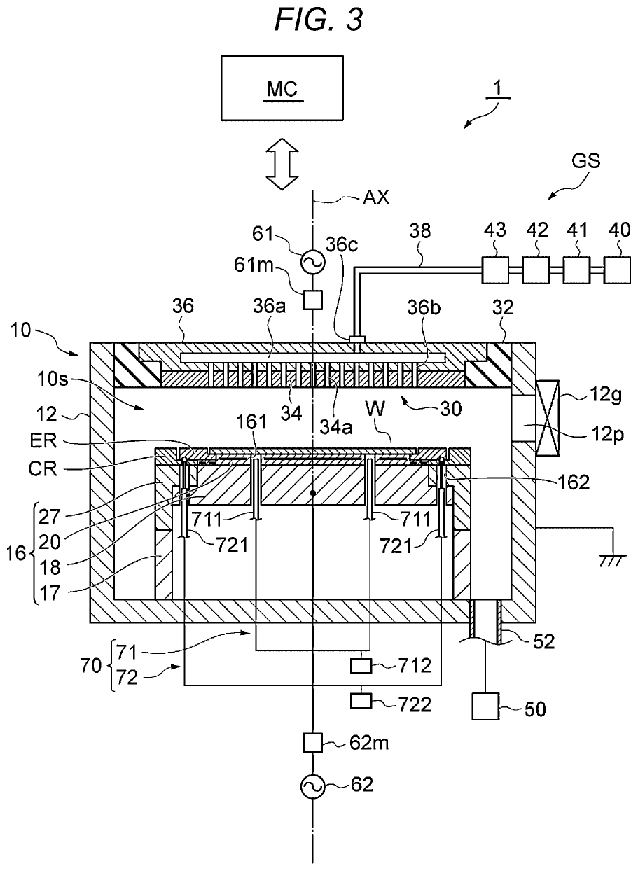

Hereinafter, FIG. 3 will be referred to. FIG. 3 is a diagram schematically showing a plasma processing apparatus according to an exemplary embodiment. A plasma processing apparatus 1 shown in FIG. 3 is adopted as at least one of the processing modules PM1 to PM7. The plasma processing apparatus 1 is a capacitively-coupled plasma processing apparatus. The plasma processing apparatus 1 includes a processing chamber 10. The processing chamber 10 has an interior space 10s therein. A central axis of the interior space 10s is an axis AX extending in a vertical direction.

In an exemplary embodiment, the processing chamber 10 includes a chamber main body 12. The chamber main body 12 has a substantially cylindrical shape. The interior space 10s is provided in the chamber main body 12. The chamber main body 12 is formed of, for example, aluminum. The chamber main body 12 is electrically grounded. A film having plasma resistance is formed on an inner wall surface of the chamber main body 12, that is, a wall surface defining the interior space 10s. The film may be a ceramic film such as a film formed by anodization or a film formed of yttrium oxide.

A passage 12p is formed in a sidewall of the chamber main body 12. The substrate W passes through the passage 12p when the substrate W is transferred between the processing chamber 10 and the transfer chamber TC. A gate valve 12g is provided along the sidewall of the chamber main body 12 for opening and closing the passage 12p.

The plasma processing apparatus 1 further includes a substrate support 16. The substrate support 16 is provided in the processing chamber 10. The substrate support 16 is configured to support the substrate W placed on the substrate support 16. The substrate W has a substantially disk shape. Details of the substrate support 16 will be described later.

The plasma processing apparatus 1 may further include an upper electrode 30. The upper electrode 30 is provided above the substrate support 16. The upper electrode 30 closes an upper opening of the chamber main body 12 together with a member 32. The member 32 has an insulating property. The upper electrode 30 is supported on an upper portion of the chamber main body 12 via the member 32.

The upper electrode 30 includes a top plate 34 and a support 36. A lower surface of the top plate 34 defines the interior space 10s. A plurality of gas holes 34a are provided in the top plate 34. Each of the plurality of gas holes 34a passes through the top plate 34 in a plate thickness direction (the vertical direction) and opens toward the interior space 10s. The top plate 34 is formed of, for example, silicon. Alternatively, the top plate 34 may have a structure in which a plasma-resistant film is provided on a surface of a member made of aluminum. The film may be a ceramic film such as a film formed by anodization or a film formed of yttrium oxide.

The support 36 detachably supports the top plate 34. The support 36 is formed of a conductive material such as aluminum. The support 36 is provided with a gas diffusion chamber 36a and a plurality of gas holes 36b therein. The plurality of gas holes 36b extend downward from the gas diffusion chamber 36a and communicate with the plurality of gas holes 34a, respectively. The support 36 includes a gas introduction port 36c. The gas introduction port 36c is connected to the gas diffusion chamber 36a. A gas supply pipe 38 is connected to the gas introduction port 36c.

A gas source group 40 is connected to the gas supply pipe 38 via a valve group 41, a flow rate controller group 42, and a valve group 43. The gas source group 40, the valve group 41, the flow rate controller group 42, and the valve group 43 constitute a gas supply GS. The gas source group 40 includes a plurality of gas sources. Each of the valve group 41 and the valve group 43 includes a plurality of valves (for example, opening/closing valves). The flow rate controller group 42 includes a plurality of flow rate controllers. Each of the plurality of flow rate controllers of the flow rate controller group 42 is a mass flow controller or a pressure control type flow rate controller. Each of the plurality of gas sources of the gas source group 40 is connected to the gas supply pipe 38 via a corresponding valve of the valve group 41, a corresponding flow rate controller of the flow rate controller group 42, and a corresponding valve of the valve group 43. The plasma processing apparatus 1 can supply gas from one or more gas sources selected from the plurality of gas sources of the gas source group 40 to the interior space 10s at an individually adjusted flow rate.

The processing chamber 10 includes an exhaust path around the substrate support 16. An exhaust pipe 52 is connected to a bottom portion of the processing chamber 10 below the exhaust path. An exhaust device 50 is connected to the exhaust pipe 52. The exhaust device 50 includes a pressure controller such as an automatic pressure control valve and a vacuum pump such as a turbomolecular pump, and can reduce pressure in the interior space 10s.

The plasma processing apparatus 1 further includes a radio-frequency power supply 61. The radio-frequency power supply 61 is a power supply that generates source radio-frequency power. The source radio-frequency power is used to generate plasma from a gas in the processing chamber 10. A frequency (a source frequency) of the source radio-frequency power is in a range of 27 MHz to 100 MHz. The radio-frequency power supply 61 is connected to the upper electrode 30 via a matching circuit 61m. The matching circuit 61m is configured to match an impedance on a load side (an upper electrode 30 side) of the radio-frequency power supply 61 with an output impedance of the radio-frequency power supply 61. Instead of the upper electrode 30, the radio-frequency power supply 61 may be connected to the substrate support 16 (for example, a lower electrode such as a base 18) via the matching circuit 61m.

The plasma processing apparatus 1 further includes a bias power supply 62. The bias power supply 62 is electrically connected to the substrate support 16 (for example, the lower electrode such as the base 18), and supplies, to the substrate support 16, an electric bias for drawing ions from plasma into the substrate W. The electric bias has a bias frequency. The bias frequency may be lower than the source frequency. The bias frequency is, for example, in a range of 100 kHz to 13.56 MHz.

The electric bias may be bias radio-frequency power having a bias frequency. In this case, the bias power supply 62 is connected to the substrate support 16 (for example, the lower electrode such as the base 18 or another electrode of the substrate support 16) via a matching circuit 62m. The matching circuit 62m matches an impedance on a load side of the bias power supply 62 with an output impedance of the bias power supply 62. Alternatively, the electric bias may be a sequence of voltage pulses. The voltage pulses may be pulses of a direct-current voltage. In this case, the plasma processing apparatus 1 does not include the matching circuit 62m.

The substrate support 16 includes the base 18 (i.e., a first base) and an electrostatic chuck 20. The base 18 has a substantially disk shape. The substrate support 16 may further include a base 17 (i.e., a second base) and an insulator 27. The base 18 may be formed of metal, such as aluminum, and may be formed as a lower electrode. The base 17 is provided on a bottom portion of the processing chamber 10. The insulator 27 is provided on the base 17 and can surround an outer periphery of the base 17, including surrounding a top surface of the base 17 and an outer side surface of the base 17. The insulator 27 is formed of an insulating material such as quartz, and extends to surround an outer periphery of the base 18 (i.e., an outer side surface of the base 18). The electrostatic chuck 20 is provided on the base 18 and can be provided directly on the base 18.

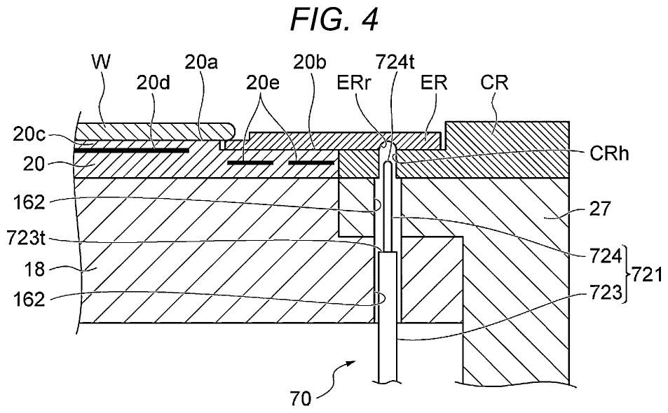

Hereinafter, FIG. 3 and FIG. 4 will be referred. FIG. 4 is a partially enlarged cross-sectional view showing a substrate support of the plasma processing apparatus according to an exemplary embodiment. An upper surface of the electrostatic chuck 20 includes a substrate support surface 20a and a ring support surface 20b. The substrate support surface 20a is substantially circular, and a central axis of the substrate support surface 20a is the axis AX. The electrostatic chuck 20 supports the substrate W placed on the substrate support surface 20a.

The ring support surface 20b is an annular surface extending around the axis AX outside the substrate support surface 20a. The electrostatic chuck 20 supports the edge ring ER placed on the ring support surface 20b. That is, the substrate support 16 can support the substrate W placed on the substrate support 16 and the edge ring ER that surrounds the substrate W. The edge ring ER has an annular shape. The substrate W is disposed in a region surrounded by the edge ring ER. The edge ring ER is made of, for example, a conductive material such as silicon or silicon carbide. The edge ring ER may be formed of an insulating material such as quartz.

The electrostatic chuck 20 includes a dielectric portion 20c, a first chuck electrode 20d, and second chuck electrodes 20e. The dielectric portion 20c is formed of ceramic such as aluminum oxide. The dielectric portion 20c has a substantially disk shape and includes the substrate support surface 20a and the ring support surface 20b.

The first chuck electrode 20d is disposed in the dielectric portion 20c and below the substrate support surface 20a. When a voltage is applied to the first chuck electrode 20d, the electrostatic chuck 20 generates an electrostatic attraction force to attract the substrate W to and hold the substrate W on the substrate support surface 20a. The second chuck electrodes 20e are disposed in the dielectric portion 20c and below the ring support surface 20b. When a voltage is applied to the second chuck electrodes 20e, the electrostatic chuck 20 generates an electrostatic attraction force to attract the edge ring ER to and hold the edge ring ER on the ring support surface 20b. In an example shown in the drawings, the electrostatic chuck 20 includes a unipolar electrostatic chuck that holds the substrate W, and a bipolar electrostatic chuck that holds the edge ring ER. Alternatively, a bipolar electrostatic chuck may be used instead of the unipolar electrostatic chuck, and a unipolar electrostatic chuck may be used instead of the bipolar electrostatic chuck.

The cover ring CR is disposed outside the edge ring ER in a manner of surrounding the edge ring ER. The cover ring CR has an annular shape. The cover ring CR covers an upper surface of the insulator 27. The cover ring CR is made of an insulating material such as quartz. The cover ring CR may be formed of a conductive material such as silicon or silicon carbide. An outer peripheral portion of the edge ring ER is disposed in a manner of overlapping an inner peripheral portion of the cover ring CR when viewed from above. Further, an outer peripheral portion of the cover ring CR is disposed outside the outer peripheral portion of the edge ring ER, and surrounds the outer peripheral portion of the edge ring ER.

The plasma processing apparatus 1 further includes a lifter 70. The lifter 70 includes a lifter 71 and a lifter 72 (see FIG. 3). The lifter 71 includes a plurality of lift pins 711 and an actuator 712. The plurality of lift pins 711 are respectively inserted into a plurality of through-holes 161 formed in the base 18 and the electrostatic chuck 20. The actuator 712 lifts and lowers the plurality of lift pins 711. The plurality of lift pins 711 can protrude upward from the substrate support surface 20a and retreat downward from the substrate support surface 20a by lifting and lowering the plurality of lift pins 711 by the actuator 712. A motor such as a DC motor, a stepping motor, or a linear motor, an air driving mechanism such as an air cylinder, or a piezo actuator can be used as the actuator 712. The lifter 71 lifts and lowers the plurality of lift pins 711 when the substrate W is transferred between the transfer robot TR and the substrate support 16.

The lifter 72 includes a plurality of lift pins 721 and an actuator 722. The plurality of lift pins 721 are respectively inserted into a plurality of through-holes 162 formed in the insulator 27 and a plurality of through-holes CRh formed in the cover ring CR. The actuator 722 lifts and lowers the plurality of lift pins 721. For example, an actuator similar to the actuator 712 can be used as the actuator 722.

Each of the plurality of lift pins 721 includes a lower portion 723 and an upper portion 724. Each of the lower portion 723 and the upper portion 724 has a rod shape. The lower portion 723 has a larger diameter than the upper portion 724. The upper portion 724 extends upward from the lower portion 723.

A diameter of each of the plurality of through-holes 162 is slightly larger than the diameter of the lower portion 723 of each of the plurality of lift pins 721. The diameter of each of the plurality of through-holes CRh is slightly larger than the diameter of the upper portion 724 of each of the plurality of lift pins 721 and smaller than the diameter of the lower portion 723 of each of the plurality of lift pins 721.

The plurality of lift pins 721 may be located at a standby position, a first support position, and the second support position. The standby position is a position where an upper end surface 724t of the upper portion 724 is located below a lower surface of the edge ring ER. In a state where the plurality of lift pins 721 are disposed at the standby position, the edge ring ER and the cover ring CR are supported by the electrostatic chuck 20 and the insulator 27, respectively, without being lifted by the plurality of lift pins 721.

The first support position is located above the standby position. In a state where the plurality of lift pins 721 are disposed at the first support position, the upper end surface 724t of the upper portion 724 is located above an upper surface of the cover ring CR, and an upper end surface 723t of the lower portion 723 is located below a lower surface of the cover ring CR. In a state where the plurality of lift pins 721 are disposed at the first support position, the upper end surface 724t of the upper portion 724 comes into contact with a surface defining a recess portion ERr formed in the lower surface of the edge ring ER. Accordingly, the plurality of lift pins 721 support the edge ring ER.

The second support position is located above the first support position. In a state where the plurality of lift pins 721 are disposed at the second support position, the upper end surface 723t of the lower portion 723 is located above an upper surface of the insulator 27. In a state where the plurality of lift pins 721 are disposed at the second support position, the upper end surface 723t of the lower portion 723 comes into contact with the lower surface of the cover ring CR. Accordingly, the plurality of lift pins 721 support the cover ring CR. When the edge ring ER is positioned on the inner peripheral portion of the cover ring CR, the upper end surface 724t of the upper portion 724 comes into contact with the surface defining the recess portion ERr, and the plurality of lift pins 721 support both the cover ring CR and the edge ring ER.

When only the edge ring ER is transferred between the transfer robot TR and the substrate support 16, the lifter 72 moves the plurality of lift pins 721 to the first support position. When both the edge ring ER and the cover ring CR or only the cover ring CR is transferred between the transfer robot TR and the substrate support 16, the lifter 72 moves the plurality of lift pins 721 to the second support position.

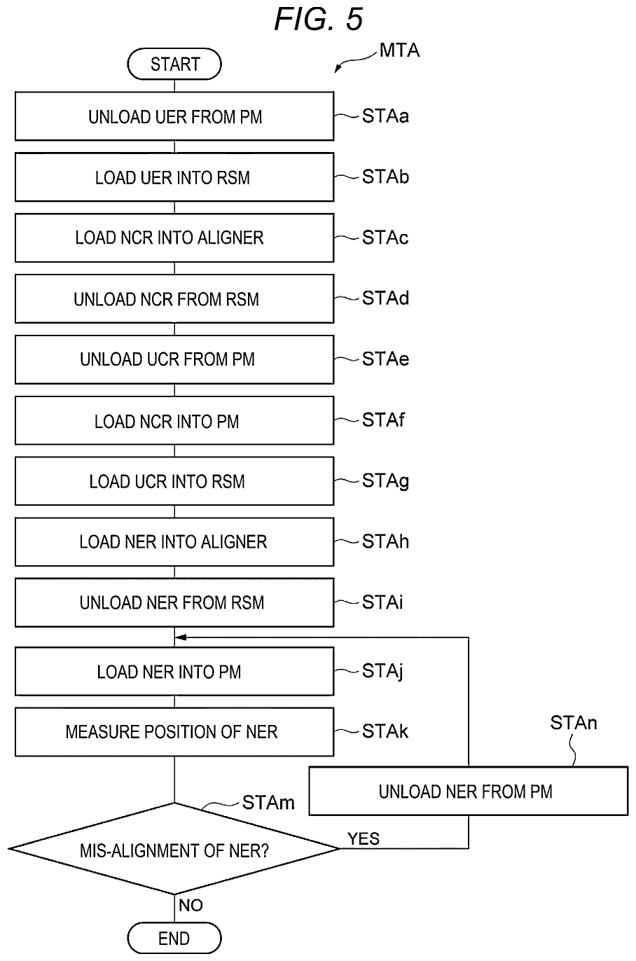

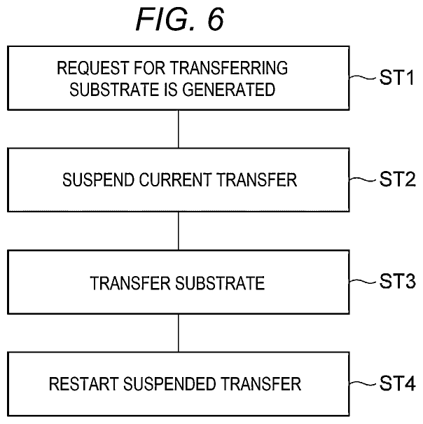

Hereinafter, a transfer method according to an exemplary embodiment will be described with reference to FIG. 5 and FIG. 6. Further, control of each component of the substrate processing system PS by the controller MC will be described. FIG. 5 is a flowchart showing a transfer method according to an exemplary embodiment. FIG. 6 is a flowchart showing substrate transfer according to an exemplary embodiment. In the transfer method shown in FIG. 5 (hereinafter referred to as a “method MTA”), each component of the substrate processing system PS is controlled by the controller MC.

The method MTA is used to replace the edge ring ER and the cover ring CR in the processing module PM. In the following description, the processing module PM is one of the processing modules PM1 to PM7 which is the plasma processing apparatus 1. In the following description, an edge ring UER is a used edge ring to be replaced with a replacement. The edge ring UER may be an edge ring consumed by use. An edge ring NER is an edge ring to be replaced with the edge ring UER. The edge ring NER may be a new or unused edge ring. The edge ring NER may be an edge ring that is already used but is not consumed. A cover ring UCR is a used ring to be replaced with a replacement. The cover ring UCR may be a cover ring consumed by use. A cover ring NCR is a cover ring to be replaced with the cover ring UCR. The cover ring NCR may be a new or unused cover ring. The cover ring NCR may be a cover ring that is already used but is not consumed.

In the method MTA, first, in step STAa, the edge ring UER is unloaded from the processing chamber 10 of the processing module PM. In step STAa, the holding (attraction) of the edge ring UER by the electrostatic chuck 20 is released. Then, the plurality of lift pins 721 of the lifter 72 are moved to the first support position. Next, one pick TP of the transfer robot TR enters the processing chamber 10 of the processing module PM. Next, the plurality of lift pins 721 of the lifter 72 are moved to the standby position to transfer the edge ring UER from the plurality of lift pins 721 of the lifter 72 to the one pick TP of the transfer robot TR in the processing chamber 10 of the processing module PM. Next, the edge ring UER is unloaded from the processing chamber 10 of the processing module PM by the transfer robot TR, and is loaded into the transfer chamber TC. In step STAa, the controller MC controls a power supply for holding the edge ring UER by the electrostatic chuck 20, the lifter 72, and the transfer robot TR.

Subsequently, in step STAb, the edge ring UER disposed on the one pick TP is loaded from the transfer chamber TC into the stocker module RSM by the transfer robot TR. In step STAb, the transfer robot TR is controlled by the controller MC.

Subsequently, in step STAc, the cover ring NCR is loaded from the cassette CST into the aligner RAN by the one pick TP of the transfer robot TR. In step STAc, the aligner RAN adjusts a position (alignment) of the cover ring NCR. In step STAc, the transfer robot TR and the aligner RAN are controlled by the controller MC.

Subsequently, in step STAd, the cover ring NCR whose position is adjusted is unloaded from the stocker module RSM and loaded into the transfer chamber TC by the one pick TP of the transfer robot TR. In step STAd, the transfer robot TR is controlled by the controller MC.

Subsequently, in step STAe, the cover ring UCR is unloaded from the processing chamber 10 of the processing module PM. In step STAe, the plurality of lift pins 721 of the lifter 72 are moved to the second support position. Next, another pick TP of the transfer robot TR enters the processing chamber 10 of the processing module PM. Next, the plurality of lift pins 721 of the lifter 72 are moved to the standby position to transfer the cover ring UCR from the plurality of lift pins 721 of the lifter 72 to the another pick TP of the transfer robot TR in the processing chamber 10 of the processing module PM. Next, the cover ring UCR is unloaded from the processing chamber 10 of the processing module PM by the transfer robot TR and loaded into the transfer chamber TC. In step STAe, the lifter 72 and the transfer robot TR are controlled by the controller MC.

Subsequently, in step STAf, the cover ring NCR is loaded from the transfer chamber TC into the processing chamber 10 of the processing module PM by the one pick TP of the transfer robot TR. In step STAf, the cover ring NCR is loaded into the processing chamber 10 of the processing module PM by the transfer robot TR. Next, the plurality of lift pins 721 of the lifter 72 are moved to the second support position to transfer the cover ring NCR from the one pick TP of the transfer robot TR to the plurality of lift pins 721. Next, the transfer robot TR retracts the one pick TP into the transfer chamber TC. Next, the plurality of lift pins 721 of the lifter 72 are moved to the standby position to dispose the cover ring NCR on the insulator 27. In step STAf, the lifter 72 and the transfer robot TR are controlled by the controller MC.

Subsequently, in step STAg, the cover ring UCR disposed on the another pick TP in the transfer chamber TC is loaded from the transfer chamber TC into the stocker module RSM by the transfer robot TR. In step STAg, the transfer robot TR is controlled by the controller MC.

Subsequently, in step STAh, the edge ring NER is loaded from the cassette CST into the aligner RAN by the one pick TP of the transfer robot TR. In step STAh, the aligner RAN adjusts a position (alignment) of the edge ring NER. In step STAh, the transfer robot TR and the aligner RAN are controlled by the controller MC.

Subsequently, in step STAi, the edge ring NER whose position is adjusted is unloaded from the stocker module RSM and loaded into the transfer chamber TC by the one pick TP of the transfer robot TR. In step STAi, the transfer robot TR is controlled by the controller MC.

Subsequently, in step STAj, the edge ring NER is loaded from the transfer chamber TC into the processing chamber 10 of the processing module PM by the one pick TP of the transfer robot TR. Specifically, in step STAj, the edge ring NER is loaded into the processing chamber 10 of the processing module PM by the transfer robot TR. Next, the plurality of lift pins 721 of the lifter 72 are moved to the first support position to transfer the edge ring NER from the one pick TP to the plurality of lift pins 721 of the lifter 72. Next, the transfer robot TR retracts the one pick TP into the transfer chamber TC. Next, the plurality of lift pins 721 of the lifter 72 are moved to the standby position to dispose the edge ring NER on the electrostatic chuck 20. The edge ring NER is held by the electrostatic chuck 20. In step STAj, the controller MC controls a power supply for holding the edge ring NER by the electrostatic chuck 20, the lifter 72, and the transfer robot TR.

Subsequently, in step STAk, a position of the edge ring NER on the substrate support 16 is measured. The position of the edge ring NER is measured by the sensor TS and is acquired by the controller MC.

Subsequently, in step STAm, the controller MC determines whether mis-alignment of the edge ring NER on the substrate support 16 occurs based on the position acquired in step STAk. When it is determined in step STAm that the mis-alignment of the edge ring NER on the substrate support 16 occurs, step STAn is executed.

In step STAn, in order to correct the position of the edge ring NER, the edge ring NER is unloaded from the processing chamber 10 of the processing module PM. In step STAn, holding of the edge ring NER by the electrostatic chuck 20 is released. Then, the plurality of lift pins 721 of the lifter 72 are moved to the first support position. Next, one pick TP of the transfer robot TR enters the processing chamber 10 of the processing module PM. Next, the plurality of lift pins 721 of the lifter 72 are moved to the standby position to transfer the edge ring NER from the plurality of lift pins 721 of the lifter 72 to the one pick TP of the transfer robot TR in the processing chamber 10 of the processing module PM. Next, the edge ring NER is unloaded from the processing chamber 10 of the processing module PM by the transfer robot TR, and is loaded into the transfer chamber TC. In step STAn, the controller MC controls a power supply for holding the edge ring NER by the electrostatic chuck 20, the lifter 72, and the transfer robot TR. Then, the processing returns to step STAj, the edge ring NER is loaded into the processing chamber 10 of the processing module PM, and is replaced on the electrostatic chuck 20. In step STAj, the position of the edge ring NER may be corrected by adjusting a position of the pick TP when the pick TP transfers the edge ring NER from the pick TP to the plurality of lift pins 721 of the lifter 72. In step STAn, after the edge ring NER is transferred from the plurality of lift pins 721 of the lifter 72 to the one pick TP of the transfer robot TR, the edge ring NER may not be unloaded from the processing chamber 10. That is, in step STAn, the position of the edge ring NER may be corrected by adjusting, in the processing chamber 10, a position of the pick TP when the pick TP transfers the edge ring NER from the pick TP to the plurality of lift pins 721 of the lifter 72 without unloading the edge ring NER from the processing chamber 10. In this case, after the position of the edge ring NER is corrected and the edge ring NER is disposed on the electrostatic chuck 20, the method MTA proceeds to step STAk.

When it is determined in step STAm that no mis-alignment of the edge ring NER on the substrate support 16 occurs, the edge ring NER is held (attracted) by the electrostatic chuck 20, and the method MTA ends. When the edge ring is not held (attracted) by the electrostatic chuck 20, holding and release of the holding of the edge ring by the electrostatic chuck 20 may be omitted in the method MTA.

The substrate processing system PS is configured to respond to a request for transferring the substrate W (a substrate transfer request) during each step of the method MTA. Specifically, when a ring member (the edge ring or the cover ring) is transferred by the transfer robot TR in each step of the method MTA, a request for transferring the substrate W may be generated in step ST1, as shown in FIG. 6. In a case where a request for transferring the substrate W is generated, step ST2 is executed when there is an unused pick TP between the at least two picks TP. In step ST2, the controller MC suspends the transfer of the ring member by the transfer robot TR in each step of the method MTA. In step ST3, the controller MC controls the transfer robot TR to transfer the substrate W using the unused pick TP. The transfer of the substrate W executed in step ST3 includes transfer of the substrate between either the load-lock module LL1 or the load-lock module LL2 and any one processing module, or between any two processing modules. When the transfer of the substrate W in step ST3 is completed, step ST4 is executed. In step ST4, the controller MC restarts the transfer of the ring member in each step that is suspended.

In the example shown in FIG. 5, when step STAe is executed, the cover ring NCR and the cover ring UCR are respectively disposed on the two picks TP. Therefore, when step STAe is executed, the substrate W is not transferred.

The order of a plurality of steps of the method MTA may be changed as long as there is no contradiction. For example, step STAc of the method MTA may be executed at any timing before the cover ring NCR is unloaded from the stocker module RSM. Step STAh of the method

MTA may be executed at any timing before the edge ring NER is unloaded from the stocker module RSM. Step STAg may be executed before step STAf. The cover ring UCR and the edge ring UER may be transferred at the same time from the processing chamber 10 of the processing module PM to the stocker module RSM by using one pick TP.

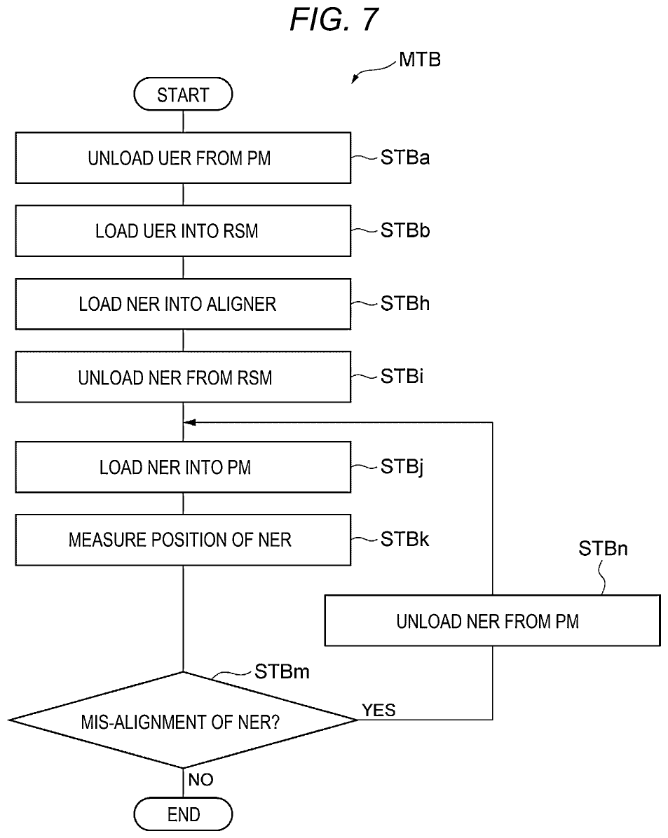

Hereinafter, FIG. 7 will be referred to. FIG. 7 is a flowchart showing a transfer method according to another exemplary embodiment. The transfer method shown in FIG. 7 (hereinafter referred to as a “method MTB”) is executed in the substrate processing system PS. The method MTB is executed to replace the edge ring ER in the processing module PM.

In the method MTB, first, in step STBa, the edge ring UER is unloaded from the processing chamber 10 of the processing module PM. Step STBa is the same as step STAa.

Subsequently, in step STBb, the edge ring UER disposed on the one pick TP is loaded from the transfer chamber TC into the stocker module RSM by the transfer robot TR. Step STBb is the same as step STAb.

Subsequently, in step STBh, the edge ring NER is loaded from the cassette CST into the aligner RAN by the one pick TP of the transfer robot TR. Step STBh is the same as step STAh.

Subsequently, in step STBi, the edge ring NER whose position is adjusted is unloaded from the stocker module RSM and loaded into the transfer chamber TC by the one pick TP of the transfer robot TR. Step STBi is the same as step STAi.

Subsequently, in step STBj, the edge ring NER is loaded from the transfer chamber TC into the processing chamber 10 of the processing module PM by the one pick TP of the transfer robot TR. Step STBj is the same as step STAj.

Subsequently, in step STBk, a position of the edge ring NER on the substrate support 16 is measured. Step STBk is the same as step STAk.

Subsequently, in step STBm, the controller MC determines whether mis-alignment of the edge ring NER on the substrate support 16 occurs based on the position acquired in step STBk. Step STBm is the same as step STAm. When it is determined in step STBm that the mis-alignment of the edge ring NER on the substrate support 16 occurs, step STBn is executed.

In step STBn, in order to correct the position of the edge ring NER, the edge ring NER is unloaded from the processing chamber 10 of the processing module PM. Step STBn is the same as step STAn. In step STBj, the edge ring NER unloaded from the processing chamber 10 in step STBn is loaded into the processing chamber 10 and replaced on the electrostatic chuck 20. In step STBn, after the edge ring NER is transferred from the plurality of lift pins 721 of the lifter 72 to the one pick TP of the transfer robot TR, the edge ring NER may not be unloaded from the processing chamber 10. That is, in step STBn, the position of the edge ring NER may be corrected by adjusting, in the processing chamber 10, a position of the pick TP when the pick TP transfers the edge ring NER from the pick TP to the plurality of lift pins 721 of the lifter 72 without unloading the edge ring NER from the processing chamber 10. In this case, after the position of the edge ring NER is corrected and the edge ring NER is disposed on the electrostatic chuck 20, the method MTA proceeds to step STBk.

When it is determined in step STBm that no mis-alignment of the edge ring NER on the substrate support 16 occurs, the edge ring NER is held (attracted) by the electrostatic chuck 20, and the method MTB ends. When the edge ring is not held (attracted) by the electrostatic chuck 20, holding and release of the holding of the edge ring by the electrostatic chuck 20 may be omitted in the method MTB.

The substrate processing system PS is configured to respond to a request for transferring the substrate W during the execution of each step of the method MTB. Specifically, when a ring member (the edge ring) is transferred by the transfer robot TR in each step of the method MTB, a request for transferring the substrate W may be generated in step ST1, as shown in FIG. 6. In a case where a request for transferring the substrate W is generated, step ST2 is executed when there is an unused pick TP between the at least two picks TP. In step ST2, the controller MC suspends the transfer of the ring member by the transfer robot TR in each step of the method MTB. In step ST3, the controller MC controls the transfer robot TR to transfer the substrate W using the unused pick TP. The transfer of the substrate W executed in step ST3 includes transfer of the substrate between either the load-lock module LL1 or the load-lock module LL2 and any one processing module, or between any two processing modules. When the transfer of the substrate W in step ST3 is completed, step ST4 is executed. In step ST4, the controller MC restarts the transfer of the ring member in each step that is suspended.

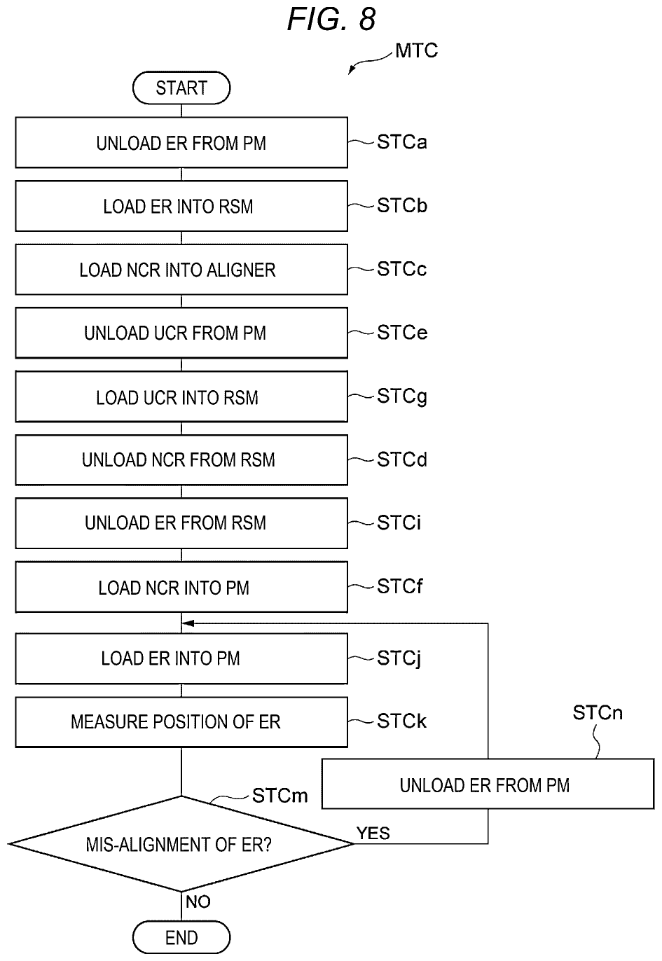

Hereinafter, FIG. 8 will be referred to. FIG. 8 is a flowchart showing a transfer method according to still another exemplary embodiment. The transfer method shown in FIG. 8 (hereinafter referred to as a “method MTC”) is executed in the substrate processing system PS. The method MTC is executed to replace the cover ring CR in the processing module PM.

In the method MTC, first, in step STCa, the edge ring ER is unloaded from the processing chamber 10 of the processing module PM. Step STCa is the same as step STAa. However, the edge ring ER unloaded from the processing chamber 10 is then returned into the processing chamber 10 of the processing module PM.

Subsequently, in step STCb, the edge ring ER disposed on the one pick TP is loaded from the transfer chamber TC into the stocker module RSM by the transfer robot TR. Step STCb is the same as step STAb.

Subsequently, in step STCc, the cover ring NCR is loaded from the cassette CST into the aligner RAN by the one pick TP of the transfer robot TR. Step STCc is the same as step STAc.

Subsequently, in step STCe, the cover ring UCR is unloaded from the processing chamber 10 of the processing module PM by the one pick TP of the transfer robot TR. Step STCe is the same as step STAe.

Subsequently, in step STCg, the cover ring UCR disposed on the one pick TP in the transfer chamber TC is loaded from the transfer chamber TC into the stocker module RSM by the transfer robot TR. Step STCg is the same as step STAg.

Subsequently, in step STCd, the cover ring NCR whose position is adjusted is unloaded from the stocker module RSM and loaded into the transfer chamber TC by the one pick TP of the transfer robot TR. Step STCd is the same as step STAd.

Subsequently, in step STCi, the edge ring ER is unloaded from the stocker module RSM and loaded into the transfer chamber TC by another pick TP of the transfer robot TR. Step STCi is the same as step STAi.

Subsequently, in step STCf, the cover ring NCR is loaded from the transfer chamber TC into the processing chamber 10 of the processing module PM by the one pick TP of the transfer robot TR. Step STCf is the same as step STAf.

Subsequently, in step STCj, the edge ring ER is loaded from the transfer chamber TC into the processing chamber 10 of the processing module PM by the another pick TP of the transfer robot TR. Step STCj is the same as step STAj. The edge ring ER transferred in step STCj may be the edge ring transferred in step STCa.

Subsequently, in step STCk, a position of the edge ring ER on the substrate support 16 is measured. Step STCk is the same as step STAk.

Subsequently, in step STCm, the controller MC determines whether mis-alignment of the edge ring ER on the substrate support 16 occurs based on the position acquired in step STCk. Step STCm is the same as step STAm. When it is determined in step STCm that the mis-alignment of the edge ring ER on the substrate support 16 occurs, step STCn is executed.

In step STCn, in order to correct the position of the edge ring ER, the edge ring ER is unloaded from the processing chamber 10 of the processing module PM. Step STCn is the same as step STAn. In step STCj, the edge ring ER unloaded from the processing chamber 10 in step STCn is loaded into the processing chamber 10 and replaced on the electrostatic chuck 20. In step STCn, after the edge ring ER is transferred from the plurality of lift pins 721 of the lifter 72 to one pick TP of the transfer robot TR, the edge ring ER may not be unloaded from the processing chamber 10. That is, in step STCn, the position of the edge ring ER may be corrected by adjusting, in the processing chamber 10, a position of the pick TP when the pick TP transfers the edge ring ER from the pick TP to the plurality of lift pins 721 of the lifter 72 without unloading the edge ring ER from the processing chamber 10. In this case, after the position of the edge ring ER is corrected and the edge ring ER is disposed on the electrostatic chuck 20, the MTC method proceeds to step STCk.

When it is determined in step STCm that no mis-alignment of the edge ring ER on the substrate support 16 occurs, the edge ring ER is held (attracted) by the electrostatic chuck 20, and the method MTC ends. When the edge ring is not held (attracted) by the electrostatic chuck 20, holding and release of the holding of the edge ring by the electrostatic chuck 20 may be omitted in the method MTC.

The substrate processing system PS is configured to respond to a request for transferring the substrate W during the execution of each step of the method MTC. Specifically, when a ring member (a cover ring) is transferred by the transfer robot TR in each step of the method MTC, a request for transferring the substrate W may be generated in step ST1, as shown in FIG. 6. In a case where a request for transferring the substrate W is generated, step ST2 is executed when there is an unused pick TP between the at least two picks TP. In step ST2, the controller MC suspends the transfer of the ring member by the transfer robot TR in each step of the method MTC. In step ST3, the controller MC controls the transfer robot TR to transfer the substrate W using the unused pick TP. The transfer of the substrate W executed in step ST3 includes transfer of the substrate between either the load-lock module LL1 or the load-lock module LL2 and any one processing module, or between any two processing modules. When the transfer of the substrate W in step ST3 is completed, step ST4 is executed. In step ST4, the controller MC restarts the transfer of the ring member in each step that is suspended.

In the example shown in FIG. 8, when step STCi is executed, the cover ring NCR and the edge ring ER are respectively disposed on the two picks TP. Therefore, when step STCi is executed, the substrate W is not transferred.

The order of a plurality of steps of the method MTC may be changed as long as there is no contradiction. For example, step STCc of the method MTC may be executed at any timing before the cover ring NCR is unloaded from the stocker module RSM.

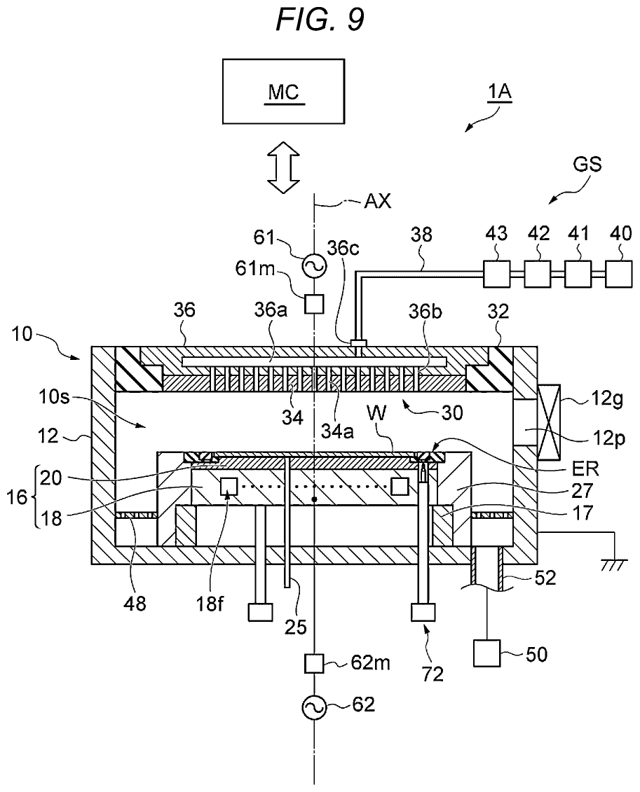

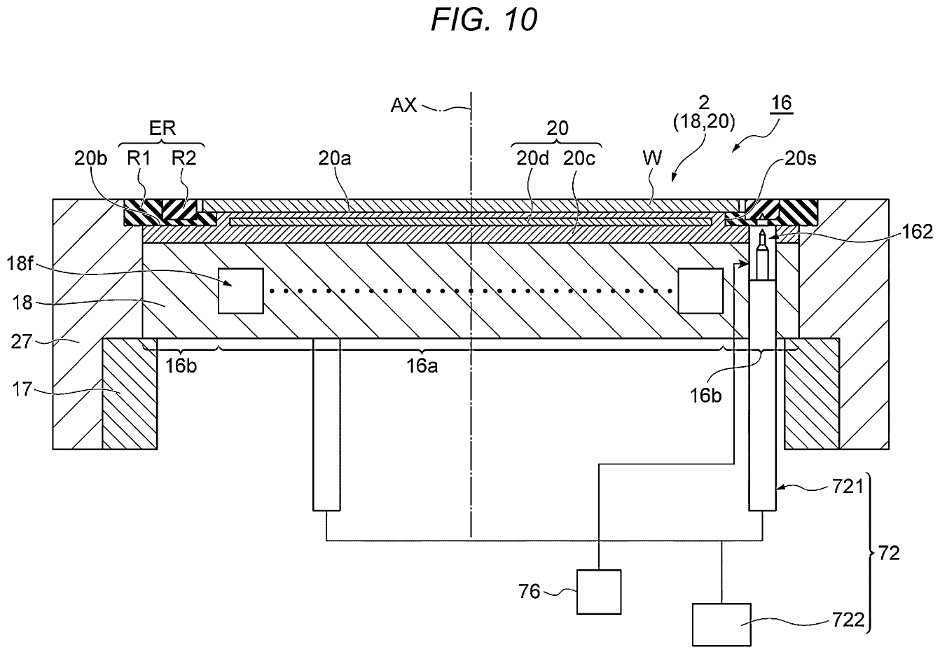

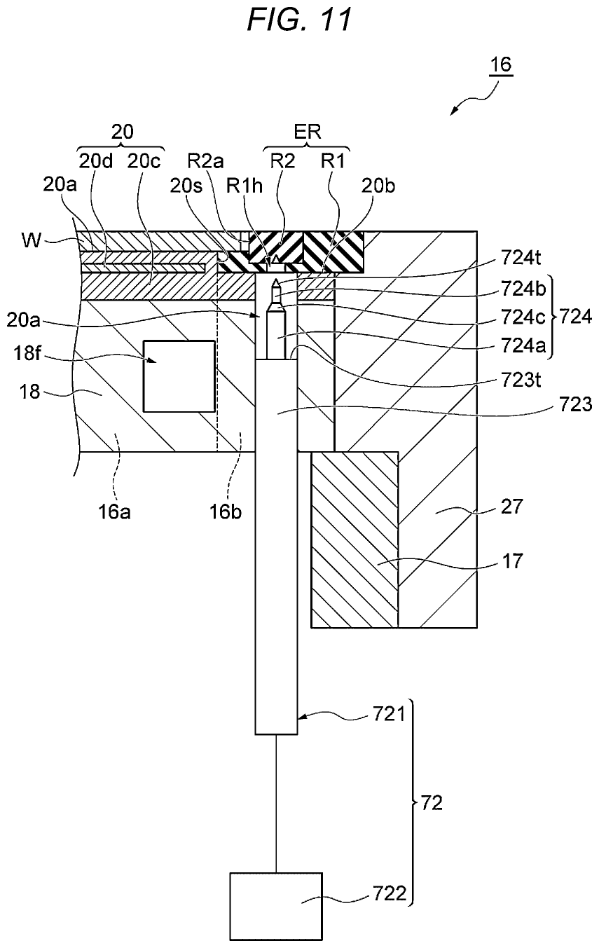

Hereinafter, FIGS. 9 to 11 will be referred to. FIG. 9 is a schematic diagram of a plasma processing apparatus according to another exemplary embodiment. FIG. 10 is a diagram schematically showing a substrate support according to another exemplary embodiment. FIG. 11 is a partially enlarged view showing the substrate support according to another exemplary embodiment. A plasma processing apparatus 1A shown in FIGS. 9 to 11 is adopted as at least one of the processing modules PM1 to PM7 of the substrate processing system PS. Hereinafter, the plasma processing apparatus 1A will be described focusing on a difference between the plasma processing apparatus 1 and the plasma processing apparatus 1A.

In the plasma processing apparatus 1A, the substrate support 16 is configured to support the substrate W placed on the substrate support 16 in the processing chamber 10. The substrate W has a substantially disk shape. A baffle plate 48 is provided between the substrate support 16 and sidewall of the processing chamber 10, that is, in an exhaust path. The baffle plate 48 may be implemented by, for example, coating an aluminum member with ceramic such as yttrium oxide. The baffle plate 48 is formed with a large number of through-holes.

The substrate support 16 of the plasma processing apparatus 1A includes a main body 2. The main body 2 includes the base 18 and the electrostatic chuck 20. The main body 2 is supported by the base 17. The base 17 extends upward from a bottom portion of the processing chamber 10. The base 17 has a substantially cylindrical shape. The base 17 is formed of an insulating material such as quartz.

The substrate support 16 has a first region 16a and a second region 16b. The first region 16a is configured to support the substrate W placed on the first region 16a. The first region 16a is substantially circular in a plan view. A central axis of the first region 16a is the axis AX. In an exemplary embodiment, the first region 16a may include a part of the base 18 and a part of the electrostatic chuck 20.

A flow path 18f is provided inside the base 18. The flow path 18f is a flow path for a heat exchange medium. Examples of the heat exchange medium include a liquid coolant and a coolant (for example, chlorofluorocarbon) for cooling the base 18 by evaporation of the coolant. The flow path 18f is connected to a supply device (for example, a chiller unit) of the heat exchange medium. The supply device is provided outside the processing chamber 10. The heat exchange medium is supplied from the supply device to the flow path 18f. The heat exchange medium supplied to the flow path 18f is returned to the supply device.

The electrostatic chuck 20 is provided on the base 18. When the substrate W is processed in the processing chamber 10, the substrate W is placed on the first region 16a and on the electrostatic chuck 20 (that is, on the substrate support surface 20a).

The electrostatic chuck 20 has a sidewall 20s extending in a vertical direction between the substrate support surface 20a and the ring support surface 20b. The ring support surface 20b is positioned lower than the substrate support surface 20a. Accordingly, an upper end portion of the sidewall 20s is connected to the substrate support surface 20a, and a lower end portion of the sidewall 20s is connected to the ring support surface 20b.

The second region 16b extends radially outward with respect to the first region 16a and surrounds the first region 16a. The second region 16b is substantially annular in a plan view. In an exemplary embodiment, the second region 16b may include another part of the base 18 and another part of the electrostatic chuck 20. The edge ring ER is placed on the second region 16b, that is, on the ring support surface 20b. The substrate W is placed in a region surrounded by the edge ring ER and on the electrostatic chuck 20. Details of the edge ring ER used in the plasma processing apparatus 1A will be described later.

The plurality of through-holes 162 are formed in the second region 16b. In an exemplary embodiment, the plurality of through-holes 162 extend in the vertical direction between the ring support surface 20b and a lower surface of the main body 2 (a lower surface of the base 18). The plurality of lift pins 721 of the lifter 72 are respectively inserted into the plurality of through-holes 162. A diameter of each of the plurality of through-holes 162 is slightly larger than a diameter of the lower portion 723 of each of the plurality of lift pins 721.

The plasma processing apparatus 1A may further include a gas supply line 25. The gas supply line 25 supplies a heat transfer gas, for example, a He gas, from a gas supply mechanism to a space between the upper surface of the electrostatic chuck 20 and a rear surface (a lower surface) of the substrate W.

In the plasma processing apparatus 1A, the insulator 27 extends circumferentially and radially outward with respect to the main body 2 to surround the main body 2. The insulator 27 may extend circumferentially and radially outward with respect to the base 17 to surround the base 17. The insulator 27 may include one or more components. The insulator 27 may be formed of an insulating material such as quartz.

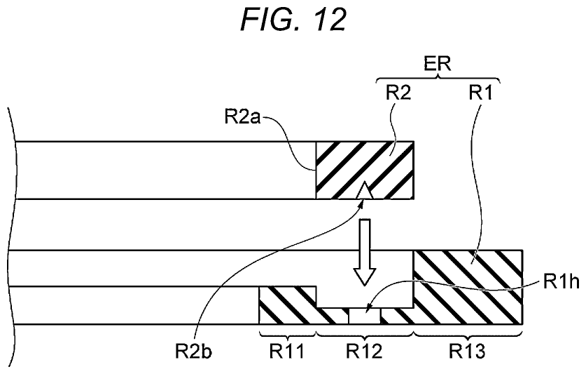

Hereinafter, the edge ring ER and the substrate support 16 in the plasma processing apparatus 1A will be described in detail with reference to FIG. 12 together with FIGS. 9 to 11. FIG. 12 is a partially enlarged cross-sectional view of the edge ring according to an exemplary embodiment. The edge ring ER used in the plasma processing apparatus 1A includes a first ring R1 and a second ring R2. Each of the first ring R1 and the second ring R2 is a ring-shaped member. The first ring R1 and the second ring R2 are formed from, for example, silicon or silicon carbide. The first ring R1 and the second ring R2 may be formed of an insulating material such as quartz.

The first ring R1 is disposed on the second region 16b, that is, the ring support surface 20b, such that a central axis of the first ring R1 is positioned on the axis AX. The first ring R1 includes an inner peripheral portion R11, an intermediate portion R12, and an outer peripheral portion R13. The inner peripheral portion R11, the intermediate portion R12, and the outer peripheral portion R13 each have an annular shape and extend around the central axis of the first ring R1.

The inner peripheral portion R11 is provided closer to the central axis of the first ring R1 than the intermediate portion R12 and the outer peripheral portion R13, and extends in a circumferential direction. The outer peripheral portion R13 extends radially outward with respect to the inner peripheral portion R11 and the intermediate portion R12. In a state where the substrate W is placed on the electrostatic chuck 20, an edge of the substrate W extends on or above the inner peripheral portion R11. The outer peripheral portion R13 is apart from the edge of the substrate W radially outward.

The intermediate portion R12 extends circumferentially between the inner peripheral portion R11 and the outer peripheral portion R13. A plurality of through-holes R1h are formed in the intermediate portion R12. The plurality of through-holes R1h are formed in the intermediate portion R12 in a manner of extending along the vertical direction. The first ring R1 is disposed on the ring support surface 20b such that the plurality of through-holes R1h are respectively aligned with the plurality of through-holes 162. A diameter of each of the through-holes R1h is smaller than a diameter of the lower portion 723 of the corresponding lift pin 721 and is larger than a diameter of the upper portion 724. Therefore, upper portions 724 of the plurality of lift pins 721 can be inserted into the corresponding through-holes R1h.

An upper surface of the intermediate portion R12 extends at a position lower than an upper surface of the inner peripheral portion R11 and an upper surface of the outer peripheral portion R13 in a height direction. Therefore, the first ring R1 defines a recess portion in the intermediate portion R12. The second ring R2 is placed on the intermediate portion R12 in a manner of being fitted into the recess portion on the intermediate portion R12. In a state where the substrate W is placed on the electrostatic chuck 20, an end face of the substrate W faces an inner peripheral surface R2a of the second ring R2.

In an exemplary embodiment, a lower surface of the inner peripheral portion R11, a lower surface of the intermediate portion R12, and a lower surface of the outer peripheral portion R13 form a single horizontal surface on a lower surface of the first ring R1. The upper surface of the inner peripheral portion R11 is positioned higher than the upper surface of the intermediate portion R12, and the upper surface of the outer peripheral portion R13 is higher than the upper surface of the inner peripheral portion R11 and the upper surface of the intermediate portion R12. That is, the inner peripheral portion R11 has a thickness smaller than a thickness of the outer peripheral portion R13. The intermediate portion R12 has a thickness smaller than the thickness of the inner peripheral portion R11 and the thickness of the outer peripheral portion R13. The substrate support surface 20a has a diameter smaller than a diameter of the substrate W, and the upper surface of the inner peripheral portion R11 faces a lower surface of an edge of the substrate W. An inner peripheral surface of the inner peripheral portion R11 faces the sidewall 20s. An outer peripheral surface of the inner peripheral portion R11 is connected to an inner peripheral end portion of the upper surface of the intermediate portion R12. An inner peripheral surface of the outer peripheral portion R13 is connected to an outer peripheral end portion of the upper surface of the intermediate portion R12. That is, the first ring R1 has a recess portion defined by the outer peripheral surface of the inner peripheral portion R11, the upper surface of the intermediate portion R12, and the inner peripheral surface of the outer peripheral portion R13.

The second ring R2 has a substantially flat lower surface. The lower surface of the second ring R2 may further include a tapered surface, and the tapered surface may define a plurality of recess portions R2b. The second ring R2 is disposed on the intermediate portion R12 such that the plurality of recess portions R2b are respectively aligned with the plurality of through-holes R1h. Each recess portion R2b has a size at which a distal end of the upper portion 724 of the corresponding lift pin 721 is fitted into the recess portion R2b.

In an exemplary embodiment, the first ring R1 and the second ring R2 are configured such that the upper surface of the outer peripheral portion R13 of the first ring R1 and an upper surface of the second ring R2 are positioned at substantially the same height as an upper surface of the substrate W disposed on the substrate support surface 20a when the first ring R1 and the second ring R2 are disposed on the ring support surface 20b. Further, the inner peripheral surface R2a of the second ring R2 faces an end surface of the substrate W disposed on the substrate support surface 20a when the first ring R1 and the second ring R2 are disposed on the ring support surface 20b.

In the plasma processing apparatus 1A, the lifter 72 is configured to lift and lower the first ring R1 and the second ring R2 using the plurality of lift pins 721. Each lift pin 721 may be formed of a material having an insulation property. Each lift pin 721 may be formed of, for example, sapphire, alumina, quartz, silicon nitride, aluminum nitride, or resin.

The plurality of lift pins 721 may be located at a standby position, a first support position, and the second support position. The standby position is a position where the upper end surface 724t of the upper portion 724 is located below the lower surface of the first ring R1. In a state where the plurality of lift pins 721 are disposed at the standby position, the first ring R1 and the second ring R2 are supported on the ring support surface 20b without being lifted by the plurality of lift pins 721.

The first support position is located above the standby position. In a state where the plurality of lift pins 721 are disposed at the first support position, the upper end surface 724t of the upper portion 724 is located above the upper surface of the intermediate portion R12 of the first ring R1, and the upper end surface 723t of the lower portion 723 is located below the lower surface of the first ring R1. In a state where the plurality of lift pins 721 are disposed at the first support position, the upper end surface 724t of the upper portion 724 comes into contact with a surface defining the recess portion R2b formed in the lower surface of the second ring R2.

Accordingly, the plurality of lift pins 721 support the second ring R2.

The second support position is located above the first support position. In a state where the plurality of lift pins 721 are disposed at the second support position, the upper end surface 723t of the lower portion 723 is located above the ring support surface 20b. In a state where the plurality of lift pins 721 are disposed at the second support position, the upper end surface 723t of the lower portion 723 comes into contact with the lower surface of the first ring R1. Accordingly, the plurality of lift pins 721 support the first ring R1. When the second ring R2 is positioned on the first ring R1, the upper end surface 724t of the upper portion 724 comes into contact with the surface defining the recess portion R2b, and the plurality of lift pins 721 support both the first ring R1 and the second ring R2.

When only the second ring R2 is transferred between the transfer robot TR and the substrate support 16, the lifter 72 moves the plurality of lift pins 721 to the first support position. When both the first ring R1 and the second ring R2 or only the first ring R1 is transferred between the transfer robot TR and the substrate support 16, the lifter 72 moves the plurality of lift pins 721 to the second support position.

In an exemplary embodiment, the upper end surface 724t of each of the plurality of lift pins 721 may be formed in a tapered shape (e.g., conical shape) to be fitted into the corresponding recess portion R2b (e.g., conical shaped recess portion). In an exemplary embodiment, the upper portion 724 may include a first portion 724a, a second portion 724b, and a third portion 724c. The first portion 724a has a columnar shape and extends upward from the lower portion 723. The second portion 724b is provided above the first portion 724a. The second portion 724b has a columnar shape and extends upward. The second portion 724b has a smaller diameter than the first portion 724a. The third portion 724c is provided between the first portion 724a and the second portion 724b. A surface of the third portion 724c has a tapered shape so as to be continuous with a surface (an outer peripheral surface) of the first portion 724a and a surface (an outer peripheral surface) of the second portion 724b.

In an exemplary embodiment, the plasma processing apparatus 1A may further include a gas supply 76. The gas supply unit 76 supplies a gas to the through-holes 162 to prevent discharge in the through-holes 162. The gas supplied from the gas supply unit 76 into the through-holes 162 is an inert gas. The gas supplied from the gas supply unit 76 into the through-holes 162 is, for example, a helium gas.

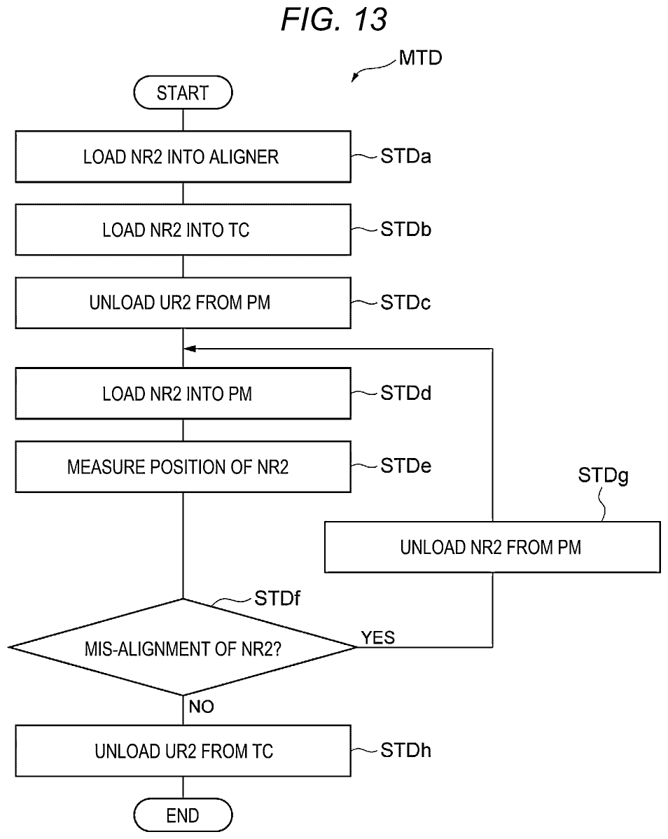

Hereinafter, a transfer method according to still another exemplary embodiment will be described with reference to FIG. 13. Further, control of each component of the substrate processing system PS by the controller MC will be described. FIG. 13 is a flowchart showing a transfer method according to still another exemplary embodiment. In the transfer method shown in FIG. 13 (hereinafter referred to as a “method MTD”), each component of the substrate processing system PS is controlled by the controller MC.

The method MTD is executed to replace the second ring R2 in the processing module PM. In the following description, the processing module PM is one of the processing modules PM1 to PM7 which is the plasma processing apparatus 1A. In the following description, a second ring UR2 is a used second ring to be replaced with a replacement. The second ring UR2 may be an edge ring consumed by use. A second ring NR2 is a second ring to be replaced with the second ring UR2. The second ring NR2 may be a new or unused edge ring. The second ring NR2 may be a second ring that is already used but is not consumed.

In step STDa of the method MTD, the second ring NR2 is loaded from any one of the containers 4a to 4d into the aligner AN by the transfer robot LR. In step STDa, the aligner AN adjusts a position (alignment) of the second ring NR2. In step STDa, the transfer robot LR and the aligner AN are controlled by the controller MC.

Subsequently, in step STDb, the second ring NR2 whose position is adjusted is loaded into the transfer chamber TC. In step STDb, the second ring NR2 is loaded into a preliminary decompression chamber of the load-lock module LL1 or the load-lock module LL2 by the transfer robot LR. Next, the second ring NR2 is unloaded from the preliminary decompression chamber and loaded into the transfer chamber TC of the transfer module TM by one pick TP of the transfer robot TR. In step STDb, the transfer robot LR and the transfer robot TR are controlled by the controller MC.

Subsequently, in step STDc, the second ring UR2 is unloaded from the processing chamber 10 of the processing module PM. In step STDc, the plurality of lift pins 721 of the lifter 72 are moved to the first support position. Next, another pick TP of the transfer robot TR enters the processing chamber 10 of the processing module PM. Next, the plurality of lift pins 721 of the lifter 72 are moved to the standby position to transfer the second ring UR2 from the plurality of lift pins 721 of the lifter 72 to the one pick TP of the transfer robot TR in the processing chamber 10 of the processing module PM. Next, the second ring UR2 is unloaded from the processing chamber 10 of the processing module PM and loaded into the transfer chamber TC by the transfer robot TR. In step STDc, the lifter 72 and the transfer robot TR are controlled by the controller MC.

Subsequently, in step STDd, the second ring NR2 is loaded from the transfer chamber TC into the processing chamber 10 of the processing module PM by another pick TP of the transfer robot TR. Specifically, in step STDd, the second ring NR2 is loaded into the processing chamber 10 of the processing module PM by the transfer robot TR. Next, the plurality of lift pins 721 of the lifter 72 are moved to the first support position to transfer the second ring NR2 from the pick TP to the plurality of lift pins 721 of the lifter 72. Next, the transfer robot TR retracts the pick TP into the transfer chamber TC. Next, the plurality of lift pins 721 of the lifter 72 are moved to the standby position to dispose the second ring NR2 on the first ring R1. In step STDd, the lifter 72 and the transfer robot TR are controlled by the controller MC.

Subsequently, in step STDe, a position of the second ring NR2 on the substrate support 16 is measured. The position of the second ring NR2 is measured by the sensor TS and is acquired by the controller MC.

Subsequently, in step STDf, the controller MC determines whether mis-alignment of the second ring NR2 on the substrate support 16 occurs based on the position acquired in step STAe. When it is determined in step STDf that the mis-alignment of the second ring NR2 on the substrate support 16 occurs, step STDg is executed.

In step STDg, in order to correct the position of the second ring NR2, the second ring NR2 is unloaded from the processing chamber 10 of the processing module PM. In step STDg, the plurality of lift pins 721 of the lifter 72 are moved to the first support position. Next, another pick TP of the transfer robot TR enters the processing chamber 10 of the processing module PM. Next, the plurality of lift pins 721 of the lifter 72 are moved to the standby position to transfer the second ring NR2 from the plurality of lift pins 721 of the lifter 72 to the pick TP of the transfer robot TR in the processing chamber 10 of the processing module PM. Next, the second ring NR2 is unloaded from the processing chamber 10 of the processing module PM and is loaded into the transfer chamber TC by the transfer robot TR. In step STDg, the lifter 72 and the transfer robot TR are controlled by the controller MC. Then, the method MTD returns to step STDd, the second ring NR2 is loaded into the processing chamber 10 of the processing module PM, and is replaced on the first ring R1. In step STDd, the position of the second ring NR2 may be corrected by adjusting a position of the pick TP when the pick TP transfers the second ring NR2 from the pick TP to the plurality of lift pins 721 of the lifter 72. In step STDg, after the second ring NR2 is transferred from the plurality of lift pins 721 of the lifter 72 to the one pick TP of the transfer robot TR, the second ring NR2 may not be unloaded from the processing chamber 10. That is, in step STDg, the position of the second ring NR2 may be corrected by adjusting, in the processing chamber 10, the position of the pick TP when the pick TP transfers the second ring NR2 from the pick TP to the plurality of lift pins 721 of the lifter 72 without unloading the second ring NR2 from the processing chamber 10. In this case, after the position of the second ring NR2 is corrected and the second ring NR2 is disposed on the first ring R1, the method MTD proceeds to step STDe.

When it is determined in step STDf that no mis-alignment of the second ring NR2 on the substrate support 16 occurs, step STDh is executed.

In step STDh, the second ring UR2 is unloaded from the transfer chamber TC. In step STDh, the second ring UR2 is unloaded from the transfer chamber TC and loaded into the preliminary decompression chamber of the load-lock module LL1 or the load-lock module LL2 by the transfer robot TR. Next, the second ring UR2 is unloaded from the preliminary decompression chamber and returned to any one of the containers 4a to 4d by the transfer robot LR. In step STDh, the transfer robot LR and the transfer robot TR are controlled by the controller MC. Then, the method MTD ends.

The substrate processing system PS is configured to respond to a request for transferring the substrate W during the execution of each step of the method MTD. Specifically, when the transfer by the transfer robot TR is performed in each step of the method MTD, a request for transferring the substrate W may be generated in step ST1, as shown in FIG. 6. In a case where a request for transferring the substrate W is generated, step ST2 is executed when there is an unused pick TP between the at least two picks TP. In step ST2, the controller MC suspends the transfer of the ring member (the second ring) by the transfer robot TR in each step of the method MTD. In step ST3, the controller MC controls the transfer robot TR to transfer the substrate W using the unused pick TP. The transfer of the substrate W executed in step ST3 includes transfer of the substrate W between either the load-lock module LL1 or the load-lock module LL2 and any one processing module, between any two processing modules, between each of the containers 4a to 4d and the aligner AN, between the aligner AN and each of the load-lock modules LL1 and LL2, or between each of the load-lock modules LL1 and LL2 and each of the containers 4a to 4d. When the transfer of the substrate W in step ST3 is completed, step ST4 is executed. In step ST4, the controller MC restarts the transfer of the ring member in each step that is suspended.

In the example shown in FIG. 13, there is a state where the two picks TP of the transfer robot TR are used in step STDc and step STDd. When such a state occurs, the substrate W is not transferred. The order of a plurality of steps of the method MTD may be changed as long as there is no contradiction. In the above description, although an example in which the second ring R2 is replaced has been described, the first ring R1 may be replaced by the same method as described above.

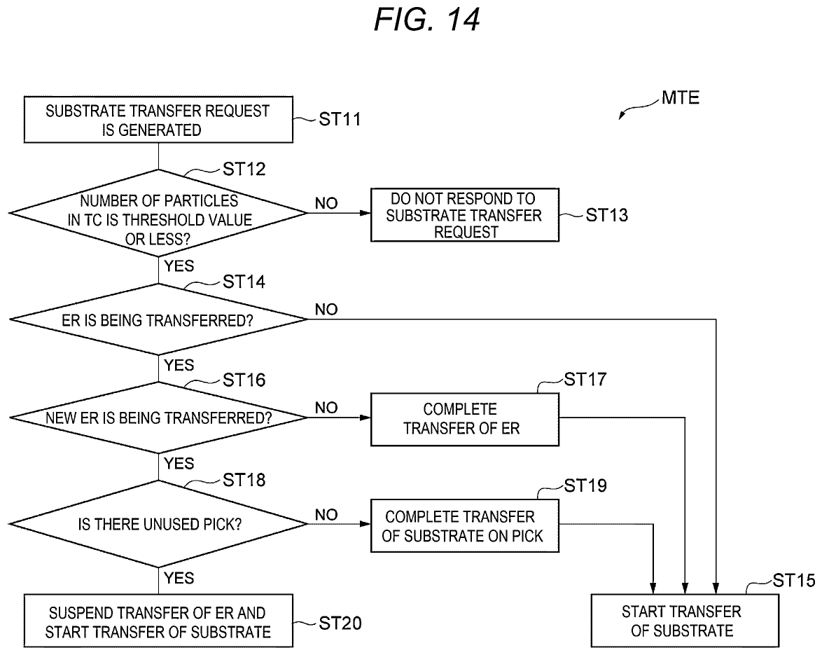

Hereinafter, a transfer method according to still another exemplary embodiment will be described with reference to FIG. 14. Further, control of each component of the substrate processing system PS by the controller MC will be described. FIG. 14 is a flowchart showing a transfer method according to still another exemplary embodiment. In the transfer method shown in FIG. 14 (hereinafter referred to as a “method MTE”), each component of the substrate processing system PS is controlled by the controller MC.

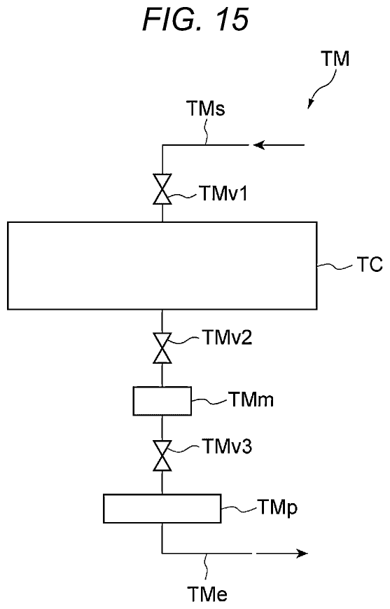

FIG. 15 is a diagram showing a transfer module according to an exemplary embodiment. In the substrate processing system PS used in the method MTE, the transfer module TM may further include a particle monitor TMm as shown in FIG. 15.

In the transfer module TM, a gas supply line TMs may be connected to the transfer chamber TC via a valve TMv1. An exhaust line TMe may be connected to the transfer chamber TC via a valve TMv2, the particle monitor TMm, a valve TMv3, and an exhaust pump TMp.

In the transfer module TM, a carrier gas such as an inert gas (for example, a noble gas) is supplied from the gas supply line TMs into the transfer chamber TC via the valve TMv1. The carrier gas is exhausted from the transfer chamber TC via the valve TMv2, the particle monitor TMm, the valve TMv3, the exhaust pump TMp, and the exhaust line TMe. When there are particles in the transfer chamber TC, the carrier gas is exhausted together with the particles from the transfer chamber TC. The particle monitor TMm is configured to monitor the particles exhausted together with the carrier gas and measure the number of the particles.

Referring back to FIG. 14, in the method MTD, a request for transferring the substrate W (a substrate transfer request) may be generated in step ST11. When the substrate transfer request is generated, in step ST12, the controller MC acquires the number of the particles in the transfer chamber TC that is measured by the particle monitor TMm. In step ST12, the controller MC determines whether the number of the particles in the transfer chamber TC is a threshold value or less. When the number of the particles in the transfer chamber TC exceeds the threshold value, the controller MC does not respond to the substrate transfer request (step ST13). When the controller MC does not respond to the substrate transfer request, cleaning or maintenance of the transfer chamber TC is performed. Thereafter, processing may be executed in response to the substrate transfer request. Step ST12 may be executed at any timing in a period in which the method MTE is executed, or may be executed constantly.

When it is determined in step ST12 that the number of the particles in the transfer chamber TC is the threshold value or less, the method MTE proceeds to step ST14. In step ST14, the controller MC determines whether the transfer robot TR is transferring the edge ring ER via the transfer chamber TC using a pick TP (an end effector). When it is determined in step ST14 that the transfer robot TR is not transferring the edge ring ER, the method MTE proceeds to step ST15. In step ST15, the controller MC controls the transfer robot TR to transfer the substrate W using the pick TP in response to the substrate transfer request. On the other hand, when it is determined in step ST14 that the transfer robot TR is transferring the edge ring ER, the method MTE proceeds to step ST16.

In step ST16, the controller MC determines whether the transfer robot TR is transferring a new edge ring ER (the edge ring NER) or a used edge ring ER (the edge ring UER) using the pick TP. In an exemplary embodiment, the controller MC may determine that the edge ring ER that is being transferred is a new edge ring ER when the edge ring ER is transferred from the stocker module RSM to any one of the plurality of processing modules PM. The controller MC may determine that the edge ring ER that is being transferred is a used edge ring ER when the edge ring ER is transferred from any one of the plurality of processing modules PM to the stocker module RSM.

When it is determined in step ST16 that the transfer robot TR is transferring a used edge ring ER instead of a new edge ring ER, the method MTE proceeds to step ST17. Step ST17 is executed before the controller MC responds to the substrate transfer request. In step ST17, the controller MC controls the transfer robot TR to complete the transfer of the edge ring ER that is being transferred, that is, the used edge ring ER. Thereafter, the method MTE proceeds to step ST15. On the other hand, when it is determined in step ST16 that the transfer robot TR is transferring a new edge ring ER, the method MTE proceeds to step ST18.

In step ST18, the controller MC determines whether there is an unused pick TP between the two picks TP. A situation in which there is no unused pick TP is, for example, a situation in which one of the two picks TP supports the new edge ring ER and the other one of the two picks TP transfers another substrate. When it is determined in step ST18 that there is no unused pick TP between the two picks TP, the method MTE proceeds to step ST19. In step ST19, the controller MC controls the transfer robot TR to complete transfer of a substrate on the pick TP. Thereafter, the method MTE proceeds to step ST15. After step ST15, the transfer of a new ER is restarted. On the other hand, when it is determined in step ST18 that there is an unused pick TP between the two picks TP, the method MTE proceeds to step ST20.

In step ST20, in response to the substrate transfer request, the controller MC suspends the transfer of the edge ring ER (the edge ring NER) that is being transferred. The controller MC controls the transfer robot TR such that the transfer robot TR transfers, via the transfer chamber TC, the substrate W requested in the substrate transfer request using the unused pick TP.

In the method MTE, the transfer robot TR is controlled such that the transfer robot TR does not transfer the used edge ring ER and the substrate W at the same time. Therefore, substrate W is prevented from being contaminated by contaminants that may be generated from the used edge ring ER. The substrate W is transferred only when the number of particles in the transfer chamber TC is the threshold value or less. Therefore, the substrate W in the transfer chamber TC is prevented from being contaminated. In the method MTE, the load-lock module LL1 or LL2 may be used instead of the stocker module RSM.

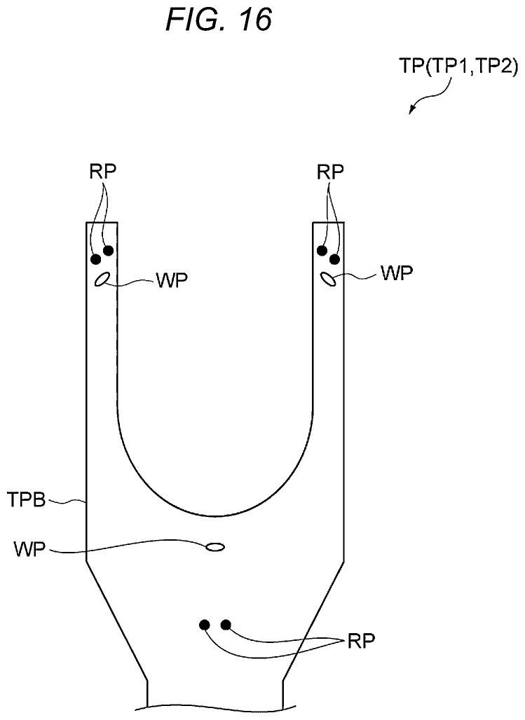

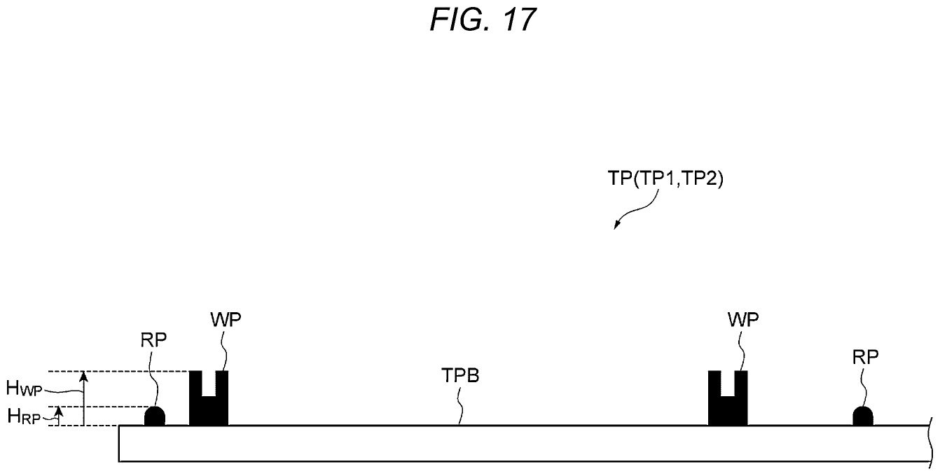

Hereinafter, examples of the two picks TP (the end effectors) of the transfer robot TR that can be adopted in the substrate processing system PS and that can be used in a transfer method according to various exemplary embodiments will be described with reference to FIGS. 16 and 17. FIG. 16 is a plan view showing an example pick. FIG. 17 is a side view showing an example pick.

The transfer robot TR may include a pick TP1 (a first end effector) and a pick TP2 (a second end effector) as the two picks TP. The pick TP1 may be dedicated to transfer of the edge ring ER from the stocker module RSM to any one of the plurality of processing modules PM. That is, the pick TP1 may be used dedicated to transfer of a new edge ring ER. The pick TP2 may be dedicated to transfer of the edge ring ER from any one of the plurality of processing modules PM to the stocker module RSM. That is, the pick TP2 may be dedicated to transfer of a used edge ring ER. In the transfer robot TR, the pick TP2 may be disposed at a position lower than the pick TP1. In this case, the pick TP1 or an object on the pick TP1 is prevented from being contaminated by the pick TP2 or contaminants of an object on the pick TP2.

As shown in FIGS. 16 and 17, each of the pick TP1 and the pick TP2 may include a plurality of substrate support pads WP and a plurality of ring support pads RP. Each of the pick TP1 and the pick TP2 may further include a blade TPB. The blade TPB has a plate shape and has a substantially horseshoe shape. The plurality of substrate support pads WP and the plurality of ring support pads RP may be provided on one major surface of the blade TPB. The plurality of substrate support pads WP are configured to support the substrate W disposed on the substrate support pads WP. The plurality of ring support pads RP are configured to support a ring member (the edge ring ER or the cover ring CR) disposed on the ring support pads RP.

The plurality of substrate support pads WP (a plurality of first substrate support pads) of the pick TP1 are configured to support the substrate W at a first height (a height Hwp in FIG. 17). The plurality of ring support pads RP (a plurality of first ring support pads) of the pick TP1 are configured to support a ring member (the edge ring ER or the cover ring CR) at a second height (a height HRP in FIG. 17). The second height is lower than the first height. When only the pick TP2 is used dedicated to transfer of a used edge ring ER, the pick TP1 does not need to have the configuration shown in FIG. 17.

The plurality of substrate support pads WP (a plurality of second substrate support pads) of the pick TP2 are configured to support the substrate W at a third height (a height Hwp in FIG. 17). The third height of the pick TP2 may be lower than the second height of the pick TP1. The plurality of ring support pads RP (a plurality of second ring support pads) of the pick TP2 are configured to support a ring member (the edge ring ER or the cover ring CR) at a fourth height (a height HRP in FIG. 17). The fourth height is lower than the third height.

According to the pick TP shown in FIGS. 16 and 17, the substrate W is placed on the pick TP at a position higher than a position in a height direction where the ring member is placed on the pick TP. Therefore, the substrate W on the pick TP is prevented from being contaminated.

In the various exemplary embodiments described above, when there is a pick available during the transfer of a ring member, transfer of the ring member that is currently performed is suspended, and a substrate is transferred. Therefore, productivity of the substrate processing system PS is increased.

Although various exemplary embodiments have been described above, various additions, omissions, substitutions and changes may be made without being limited to the exemplary embodiments described above. In addition, other embodiments may be formed by combining elements in different embodiments.

For example, in various exemplary embodiments, even when a request for transferring a substrate is generated in a state where both of the two picks TP are not used during an operation of replacing a ring member, the transfer robot may be controlled to suspend the transfer of the ring member and transfer the substrate.

In the embodiment described with reference to FIGS. 9 to 13, the edge ring ER may not include two rings (the first ring R1 and the second ring R2), and may include a single ring.

The number of picks TP of the transfer robot TR may be one. In this case, the ring member described above is transferred using a single pick TP. In a case where the ring member is transferred using a single pick TP, when a request for transferring the substrate W is generated, the ring member that is currently transferred is disposed in a standby location, and the transfer of the ring member is suspended. Then, the substrate W is transferred using the single pick TP. When the transfer of the substrate W is completed, the suspended transfer of the ring member is restarted.

The plasma processing apparatus adopted in the substrate processing system PS may be a plasma processing apparatus other than the capacitively-coupled plasma processing apparatus. The plasma processing apparatus may be an inductively-coupled plasma processing apparatus, a plasma processing apparatus that generates plasma by surface waves, or an electron cyclotron resonance (ECR) plasma processing apparatus.

The ring member (the edge ring ER or the cover ring CR) that is transferred using the transfer methods according to the various exemplary embodiments is a consumable part used in at least one of the plurality of processing modules PM. In the transfer methods according to various exemplary embodiments, instead of the ring member described above, another consumable part used in at least one of the plurality of processing modules PM may be transferred by the transfer robot TR. For example, the another consumable part is an upper electrode used in at least one of the plurality of processing modules PM.

Hereinafter, various exemplary embodiments included in the present disclosure will be described in the following [E1] to [E22].

### [E1]

A substrate processing system including:
a transfer module that includes a decompressible transfer chamber, and a transfer robot having at least two picks and configured to transfer a substrate via the transfer chamber;
a plurality of processing modules each having a processing chamber connected to the transfer chamber; and
a controller configured to control the transfer robot, in which
the controller is configured to
   control the transfer robot to transfer a ring member for a substrate support in one processing module of the plurality of processing modules using one of the at least two picks, and
   when there is an unused pick between the at least two picks during the transfer of the ring member, control the transfer robot to suspend the transfer of the ring member and transfer the substrate via the transfer chamber using the unused pick, in response to a request for transferring the substrate.

### [E2]

The substrate processing system according to E1, in which
the ring member includes an edge ring that is used to surround the substrate on the substrate support, and
the transfer of the ring member includes unloading the edge ring from the processing chamber of the one processing module.

### [E3]

The substrate processing system according to E1 or E2, in which
the ring member includes an edge ring that is used to surround the substrate on the substrate support, and
the transfer of the ring member includes loading the edge ring into the processing chamber of the one processing module.

### [E4]

The substrate processing system according to any one of E1 to E3, in which
the ring member includes an edge ring that is used to surround the substrate on the substrate support, and
the transfer of the ring member includes unloading the edge ring placed on the substrate support from the processing chamber in order to correct a position of the edge ring.

### [E5]

The substrate processing system according to any one of E1 to E4, in which
the ring member includes a cover ring that is used to surround, on the substrate support, the edge ring used to surround the substrate on the substrate support, and
the transfer of the ring member includes unloading the cover ring from the processing chamber of the one processing module.

### [E6]

The substrate processing system according to any one of E1 to E5, in which
the ring member includes a cover ring that is used to surround, on the substrate support, the edge ring used to surround the substrate on the substrate support, and
the transfer of the ring member includes loading the cover ring into the processing chamber of the one processing module.

### [E7]

The substrate processing system according to any one of E1 to E6, further including: a stocker module configured to accommodate the ring member therein.

### [E8]

The substrate processing system according to E7, in which
the ring member includes an edge ring that is used to surround the substrate on the substrate support, and
the transfer of the ring member includes loading, into the stocker module, the edge ring unloaded from the processing chamber of the one processing module.

### [E9]

The substrate processing system according to E7 or E8, in which
the ring member includes an edge ring that is used to surround the substrate on the substrate support, and
the transfer of the ring member includes unloading the edge ring from the stocker module.

### [E10]

The substrate processing system according to any one of E7 to E9, in which
the ring member includes a cover ring that is used to surround, on the substrate support, the edge ring used to surround the substrate on the substrate support, and
the transfer of the ring member includes unloading the cover ring from the stocker module.

### [E11]

The substrate processing system according to any one of E7 to E10, in which
the ring member includes a cover ring that is used to surround, on the substrate support, the edge ring used to surround the substrate on the substrate support, and
the transfer of the ring member includes loading the cover ring into the stocker module.

### [E12]

The substrate processing system according to any one of E7 to E11, in which the stocker module includes an aligner for adjusting a position of the ring member.

### [E13]

The substrate processing system according to E12, in which
the ring member includes an edge ring that is used to surround the substrate on the substrate support, and
the transfer of the ring member includes loading the edge ring disposed in the stocker module into the aligner in order to adjust a position of the edge ring.

### [E14]

The substrate processing system according to E12 or E13, in which the ring member includes a cover ring that is used to surround, on the substrate support, the edge ring used to surround the substrate on the substrate support, and
the transfer of the ring member includes loading the cover ring disposed in the stocker module into the aligner in order to adjust a position of the cover ring.

### [E15]

The substrate processing system according to E1, in which
the one processing module is configured to use an edge ring on the substrate support,
the edge ring includes a first ring disposed on the substrate support, and a second ring disposed on the first ring in a manner of surrounding the substrate, and
the ring member is the second ring.

### [E16]

The substrate processing system according to E15, in which
the transfer of the ring member includes loading the second ring from the transfer chamber into the processing chamber of the one processing module.

### [E17]

The substrate processing system according to E15 or E16, in which
the transfer of the ring member includes unloading the second ring from the processing chamber in order to correct a position of the second ring placed on the first ring.

### [E18]

The substrate processing system according to any one of E15 to E17, further including:
a loader module including another transfer chamber whose inner pressure is set to an atmospheric pressure and another transfer robot disposed in the another transfer chamber; and
a load-lock module connected between the transfer chamber of the transfer module and the another transfer chamber of the loader module.

### [E19]

The substrate processing system according to E18, in which
the transfer of the ring member includes loading the second ring from the loader module into the transfer chamber via the load-lock module.

### [E20]

The substrate processing system according to E18 or E19, further including:
an aligner connected to the another transfer chamber, in which
the transfer of the ring member includes loading the second ring into the aligner in order to adjust a position of the second ring.

### [E21]

A substrate processing system including:
a transfer module that includes a decompressible transfer chamber and a transfer robot configured to transfer a substrate via the transfer chamber;
a plurality of processing modules each having a processing chamber connected to the transfer chamber; and
a controller configured to control the transfer robot, in which
the controller is configured to
   control the transfer robot to transfer a ring member for a substrate support in one processing module of the plurality of processing modules, and
   during the transfer of the ring member, control the transfer robot to suspend the transfer of the ring member and transfer the substrate via the transfer chamber in response to a request for transferring the substrate.

### [E22]

A transfer method including:
transferring, using a transfer module of a substrate processing system, a ring member for a substrate support in one processing module of a plurality of processing modules, the substrate processing system including the transfer module that includes a decompressible transfer chamber and a transfer robot having at least two picks and configured to transfer a substrate via the transfer chamber, and the plurality of processing modules each having a processing chamber connected to the transfer chamber;
suspending the transfer of the ring member using one pick of the at least two picks in response to a request for transferring a substrate when there is an unused pick between the at least two picks during the transfer of the ring member; and transferring the substrate via the transfer chamber using the unused pick in a state where the transfer of the ring member is suspended.

From the foregoing, it will be appreciated that various embodiments of the present disclosure have been described herein for purposes of illustration, and that various modifications may be made without departing from the scope and spirit of the present disclosure. Therefore, the various embodiments disclosed herein are not intended to be limiting, with the true scope and spirit being indicated by the following claims.

1. A substrate processing system comprising:
a vacuum transfer chamber;
a plurality of substrate processing modules that are connected to the vacuum transfer chamber, each of the plurality of substrate processing modules including a substrate processing chamber, and a substrate support disposed in the substrate processing chamber and for supporting a substrate placed thereon and an edge ring that surrounds the substrate;
a ring stocker connected to the vacuum transfer chamber and for storing the edge ring;
a transfer robot disposed in the vacuum transfer chamber and including at least two end effectors; and
a control circuitry configured to:
(a) determine whether the transfer robot is transferring the edge ring via the vacuum transfer chamber in response to a substrate transfer request,
(b) determine whether the edge ring that is being transferred is transferred from the ring stocker to any one of the plurality of substrate processing modules, or the edge ring that is being transferred is transferred from any one of the plurality of substrate processing modules to the ring stocker when it is determined in (a) that the transfer robot is transferring the edge ring, and
(c) control the transfer robot to suspend the transfer of the edge ring that is being transferred from the ring stocker to any one of the plurality of substrate processing modules and transfer the substrate via the vacuum transfer chamber using an unused end effector of the at least two end effectors when it is determined in (b) that the edge ring that is being transferred is transferred from the ring stocker to any one of the plurality of substrate processing modules.

2. The substrate processing system according to claim 1, wherein
the control circuitry is further configured to (d) control the transfer robot to complete the transfer of the edge ring that is being transferred from any one of the substrate processing modules to the ring stocker before responding to the substrate transfer request when it is determined in (b) that the edge ring that is being transferred is transferred from any one of the plurality of substrate processing modules to the ring stocker.

3. The substrate processing system according to claim 1, further comprising:
a particle monitor for monitoring particles in the vacuum transfer chamber, wherein
the control circuitry is further configured not to respond to the substrate transfer request when a number of the particles in the vacuum transfer chamber exceeds a threshold value.

4. The substrate processing system according to claim 1, wherein
the at least two end effectors include
a first end effector for transferring the edge ring from the ring stocker to any one of the plurality of substrate processing modules, and
a second end effector for transferring the edge ring from any one of the plurality of substrate processing modules to the ring stocker.

5. The substrate processing system according to claim 4, wherein
the second end effector is disposed at a position lower than the first end effector.

6. The substrate processing system according to claim 5, wherein
the first end effector includes
a plurality of first substrate support pads for supporting a substrate at a first height, and
a plurality of first ring support pads for supporting the edge ring at a second height lower than the first height, and
the second end effector includes
a plurality of second substrate support pads for supporting a substrate at a third height lower than the second height, and
a plurality of second ring support pads for supporting the edge ring at a fourth height lower than the third height.

7. The substrate processing system according to claim 5, wherein
the second end effector includes
a plurality of substrate support pads for supporting a substrate at a first height, and
a plurality of ring support pads for supporting the edge ring at a second height lower than the first height.

8. The substrate processing system according to claim 1, wherein the ring stocker includes an aligner for adjusting a position of the substrate.

9. A substrate processing system comprising:
a vacuum transfer chamber;
a plurality of substrate processing modules connected to the vacuum transfer chamber, each of the plurality of substrate processing modules including a substrate processing chamber, and a substrate support disposed in the substrate processing chamber and for supporting a substrate placed thereon and an edge ring that surrounds the substrate;
a load-lock module connected to the vacuum transfer chamber;
a transfer robot disposed in the vacuum transfer chamber and including at least two end effectors; and
a control circuitry configured to
(a) determine whether the transfer robot is transferring the edge ring via the vacuum transfer chamber in response to a substrate transfer request,
(b) determine whether the edge ring that is being transferred is transferred from the load-lock module to any one of the plurality of substrate processing modules, or the edge ring that is being transferred is transferred from any one of the plurality of substrate processing modules to the load-lock module when it is determined in (a) that the transfer robot is transferring the edge ring, and
(c) control the transfer robot to suspend the transfer of the edge ring that is being transferred from the load-lock module to any one of the plurality of substrate processing modules and transfer the substrate via the vacuum transfer chamber using an unused end effector of the at least two end effectors when it is determined in (b) that the edge ring that is being transferred is transferred from the load-lock module to any one of the plurality of substrate processing modules.

10. The substrate processing system according to claim 9, wherein
the control circuitry is configured to (d) control the transfer robot to complete the transfer of the edge ring that is being transferred from any one of the plurality of substrate processing modules to the load-lock module before responding to the substrate transfer request when it is determined in (b) that the edge ring that is being transferred is transferred from any one of the plurality of substrate processing modules to the load-lock module.

11. The substrate processing system according to claim 9, further comprising:
a particle monitor for monitoring particles in the vacuum transfer chamber, wherein
the control circuitry is configured not to respond to the substrate transfer request when
the number of the particles in the vacuum transfer chamber exceeds a threshold value.

12. The substrate processing system according to claim 9, wherein
the at least two end effectors include
a first end effector for transferring the edge ring from the load-lock module to any one of the plurality of substrate processing modules, and
a second end effector for transferring the edge ring from any one of the plurality of substrate processing modules to the load-lock module.

13. The substrate processing system according to claim 12, wherein
the second end effector is disposed at a position lower than the first end effector.

14. The substrate processing system according to claim 13, wherein
the first end effector includes
a plurality of first substrate support pads for supporting a substrate at a first height, and
a plurality of first ring support pads for supporting the edge ring at a second height lower than the first height, and
the second end effector includes
a plurality of second substrate support pads for supporting a substrate at a third height lower than the second height, and a plurality of second ring support pads for supporting the edge ring at a
fourth height lower than the third height.

15. The substrate processing system according to claim 13, wherein
the second end effector includes
a plurality of substrate support pads for supporting a substrate at a first height, and
a plurality of ring support pads for supporting the edge ring at a second height lower than the first height.

16. A substrate processing system comprising:
a vacuum transfer chamber;
a plurality of substrate processing modules connected to the vacuum transfer chamber and for using a consumable part in each of the substrate processing modules;
a transfer robot disposed in the vacuum transfer chamber and including at least two end effectors; and
a control circuitry configured to
(a) determine whether the transfer robot is transferring the consumable part via the vacuum transfer chamber in response to a substrate transfer request,
(b) determine whether the consumable part that is being transferred is a new consumable part or a used consumable part when it is determined in (a) that the transfer robot is transferring the consumable part, and
(c) control the transfer robot to suspend the transfer of the consumable part that is being transferred and transfer a substrate via the vacuum transfer chamber using an unused end effector of the at least two end effectors when it is determined in (b) that the consumable part that is being transferred is the new consumable part.

17. The substrate processing system according to claim 16, wherein
the control circuitry is further configured to (d) control the transfer robot to complete the transfer of the consumable part that is being transferred before responding to the substrate transfer request when it is determined in (b) that the consumable part that is being transferred is a used consumable part.

18. The substrate processing system according to claim 16, further comprising:
a particle monitor for monitoring particles in the vacuum transfer chamber, wherein
the control circuitry is further configured not to respond to the substrate transfer request when the number of the particles in the vacuum transfer chamber exceeds a threshold value.

19. The substrate processing system according to claim 16, wherein
each of the plurality of substrate processing modules includes
a substrate processing chamber,
a substrate support disposed in the substrate processing chamber and for supporting a substrate placed thereon and the edge ring that surrounds the substrate, and
the consumable part is in the form of a cover ring and the consumable part surrounds the edge ring.

20. The substrate processing system according to claim 16, wherein the at least two end effectors include
a first end effector for transferring the new consumable part, and
a second end effector for transferring the used consumable part.
